(19) United States
(12) Patent Application Publication
(10) Pub. No.: US 2010/0051326 A1
(43) Pub. Date: Mar. 4, 2010

(54) FLEX-RIGID WIRING BOARD AND ELECTRONIC DEVICE

(75) Inventor: Katsumi Sagisaka, Ogaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IBIDEN CO., LTD., Ogaki-shi (JP)

(21) Appl. No.: 12/494,553

(22) Filed: Jun. 30, 2009

Related U.S. Application Data
(60) Provisional application No. 61/093,052, filed on Aug. 29, 2008.

(51) Int. Cl. H05K 1/00

(52) U.S. Cl. 174/254

(57) ABSTRACT

A flex-rigid wiring board including a rigid printed wiring board having a rectangular shape and having a rigid base material and a conductor, and a flexible printed wiring board having a flexible base material and a conductor formed over the flexible base material. The conductor of the flexible printed wiring board is electrically connected to the conductor of the rigid printed wiring board. The flexible printed wiring board is connected to the rigid printed wiring board and extends from one or more sides of the rectangular shape of the rigid printed wiring board such that the flexible printed wiring board extends in a direction which makes an acute angle with respect to one or more sides of the rectangular shape of the rigid printed wiring board.

### CROSS-REFERENCE TO RELATED APPLICATIONS

The present application claims the benefits of priority to U.S. Application No. 61/093,052, filed Aug. 29, 2008. The contents of that application are incorporated herein by reference in their entirety.

### BACKGROUND OF THE INVENTION

1. Field of the Invention

The present invention is related to a bendable flex-rigid wiring board, part of which is formed with a flexible substrate, and to an electronic device using the flex-rigid wiring board.

2. Discussion of the Background

Conventionally, an electronic device is known in which a rigid substrate with a mounted electronic component is sealed in packaging (PKG) of any type and is mounted on a motherboard by means of, for example, a pin connection or a solder connection. For example, as shown in FIG. 40, in Japanese Patent Laid-Open Publication 2004-186375, as for a structure to electrically connect multiple rigid substrates 1001, 1002 which are mounted on motherboard 1000, a structure (mid-air highway structure) is disclosed where flexible substrate 1003 is connected to connectors (1004a, 1004b) arranged on the surfaces of rigid substrates 1001, 1002 respectively, and rigid substrates 1001, 1002 and electronic components (1005a, 1005b) mounted on their surfaces are electrically connected with each other through flexible substrate 1003. The contents of this publication are incorporated herein by reference in their entirety.

### SUMMARY OF THE INVENTION

According to one aspect of the present invention, a flex-rigid wiring board includes a rigid printed wiring board having a rectangular shape and having a rigid base material and a conductor, and a flexible printed wiring board having a flexible base material and a conductor formed over the flexible base material. The conductor of the flexible printed wiring board is electrically connected to the conductor of the rigid printed wiring board. The flexible printed wiring board is connected to the rigid printed wiring board and extends from one or more sides of the rectangular shape of the rigid printed wiring board such that the flexible printed wiring board extends in a direction which makes an acute angle with respect to one or more sides of the rectangular shape of the rigid printed wiring board.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a flex-rigid wiring board according to an embodiment of the present invention;

FIG. 2 is a cross-sectional view seen from the A1-A1 line in FIG. 1;

FIG. 3A is a view showing a layout example of a flex-rigid wiring board according to an embodiment of the present invention;

FIG. 3B is a view showing a layout example for comparison;

FIG. 4 is a cross-sectional view of a flexible printed wiring board;

FIG. 5 is a cross-sectional view of a flex-rigid wiring board;

FIG. 6 is a partially magnified view of FIG. 5;

FIG. 7 shows views to illustrate steps to cut out flexible printed wiring boards from a wafer commonly used for multiple products;

FIG. 8 shows views to illustrate steps to cut out first and second insulation layers from a wafer commonly used for multiple products;

FIG. 9 shows views to illustrate steps to cut out separators from a wafer commonly used for multiple products;

FIG. 10 shows views to illustrate steps to manufacture cores for rigid printed wiring boards;

FIGS. 11A-11F are views to illustrate steps to form a first layer;

FIGS. 12A-12D are views to illustrate steps to form a second layer;

FIG. 13 shows views to illustrate steps to cut out third and fourth upper-layer insulation layers from a wafer commonly used for multiple products;

FIGS. 14A-14D are views to illustrate steps to form a third layer;

FIGS. 15A-15E are views to illustrate steps to form a fourth layer;

FIG. 16A is a view to illustrate a step to expose part (a center portion) of a flexible printed wiring board;

FIG. 16B is a view showing a stage in which the center portion of the flexible printed wiring board is exposed;

FIG. 16C is a view showing a stage in which remaining copper is removed;

FIG. 17 is a view showing an example of a flex-rigid wiring board having three or more rigid printed wiring boards;

FIG. 18 is a view showing a modified example of a flex-rigid wiring board having three or more rigid printed wiring boards;

FIG. 19 is a view showing a modified example of how to arrange rigid printed wiring boards;

FIG. 20 is a view showing an example of a flexible printed wiring board with a fork;

FIG. 21 is a view showing a modified example of a flexible printed wiring board with a fork;

FIG. 22 is a view showing an example of a flex-rigid wiring board in which a flexible printed wiring board is diagonally connected to only one side of a rigid printed wiring board;

FIG. 23 is a view showing a modified example of a flex-rigid wiring board in which a flexible printed wiring board is diagonally connected to only one side of a rigid printed wiring board;

FIG. 24 is a view showing an example of a flex-rigid wiring board having a forked flexible printed wiring board;

FIG. 25 is a view showing a modified example of a flex-rigid wiring board having a forked flexible printed wiring board;

FIG. 26 is a view showing an example of a flex-rigid wiring board having two or more flexible printed wiring boards positioned by being shifted in the direction toward the thickness (vertically) of the rigid printed wiring boards;

FIG. 27 is a cross-sectional view showing an example seen from the A1-A1 line of FIG. 26;

FIG. 28 is a cross-sectional view showing a modified example seen from the A1-A1 line of FIG. 26;

FIG. 29A is a view showing a modified example of a flex-rigid wiring board having two or more flexible printed wiring boards positioned by being shifted in the direction toward the thickness (vertically) of the rigid printed wiring boards;

FIG. 29B is a view showing another modified example of a flex-rigid wiring board having two or more flexible printed wiring boards positioned by being shifted in the direction toward the thickness (vertically) of the rigid printed wiring boards;

FIG. 30A is a cross-sectional view seen from the A1-A1 line of either FIG. 29A or FIG. 29B;

FIG. 30B is a cross-sectional view seen from the A2-A2 line of either FIG. 29A or FIG. 29B;

FIG. 31A is a view showing an example of a flex-rigid wiring board having conductive patterns that fan out;

FIG. 31B is a view showing an example of a flex-rigid wiring board in which distances between vias widen from the component-connected surface toward the board-connected surface;

FIG. 32 is a view showing a modified example of how to mount a flex-rigid wiring board;

FIG. 33 is a view showing another modified example of how to mount a flex-rigid wiring board;

FIG. 34 is a view showing yet another modified example of how to mount a flex-rigid wiring board;

FIG. 35 is a view showing yet another modified example of how to mount a flex-rigid wiring board;

FIG. 36 is a view showing yet another modified example of how to mount a flex-rigid wiring board;

FIG. 37A is a view showing a connection structure for a rigid printed wiring board and a flexible printed wiring board;

FIG. 37B is a view showing a modified connection structure for a rigid printed wiring board and a flexible printed wiring board;

FIG. 37C is a view showing another modified connection structure for a rigid printed wiring board and a flexible printed wiring board;

FIG. 38 is a cross-sectional view showing a modified example of a flex-rigid wiring board;

FIG. 39 is a view showing an example of a flex-rigid wiring board having a flying-tail structure; and

FIG. 40 is a cross-sectional view showing an example of a flex-rigid wiring board having a mid-air highway structure.

### DETAILED DESCRIPTION OF THE EMBODIMENTS

The embodiments will now be described with reference to the accompanying drawings, wherein like reference numerals designate corresponding or identical elements throughout the various drawings.

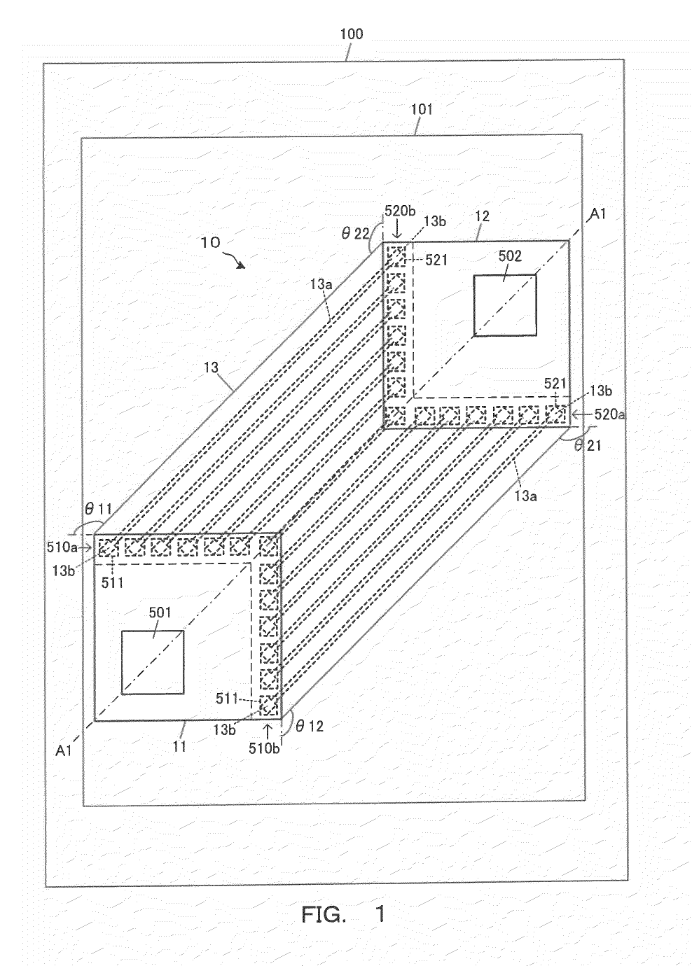

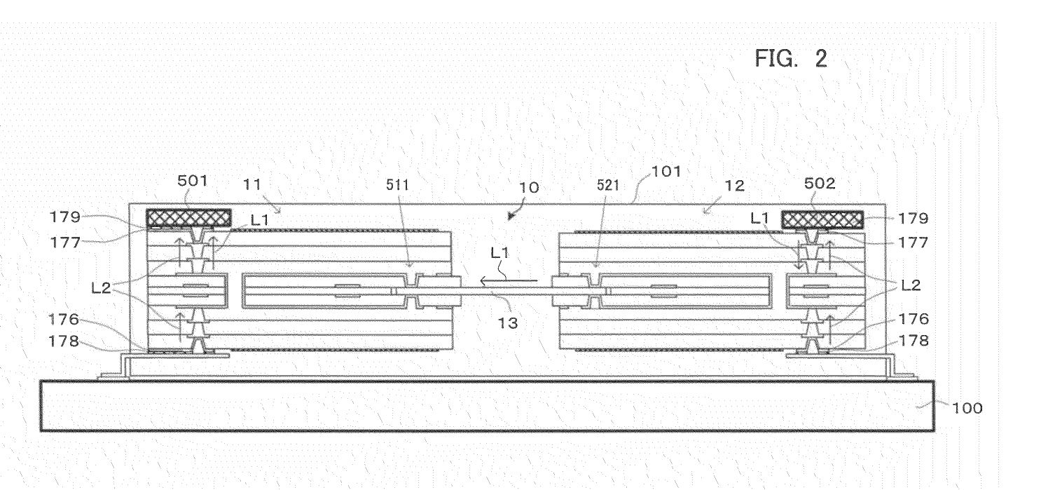

As its plane structure and cross-sectional structure are shown in FIG. 1 and FIG. 2 (a cross-sectional view seen from the A1-A1 line in FIG. 1) respectively, an electronic device of the present embodiment has a structure where flex-rigid wiring board 10 is mounted by surface mounting through, for example, soldering on a surface of motherboard 100, which is a rigid substrate, and is sealed in rectangular packaging 101, for example. Here, packaging 101 is not limited to any configuration, but, for example, a square may be employed. The material for packaging 101 is not limited to any kind, but packaging made of, for example, metal, ceramics or plastics may be used. In addition, packaging 101 is not limited to a specific type, but any packaging of, for example, DIP, QFP, PGA, BGA, CSP or the like may be used. Motherboard 100 is a printed wiring board of a sufficient size to install multiple printed circuit boards, and which has connection terminals to be connected to the printed circuit boards. It includes an expansion board (daughter board) or the like. Here, as for motherboard 100, a rigid printed wiring board is used that has a greater wiring pitch (larger pitch width) than that in rigid substrates 11, 12. Also, any method for mounting flex-rigid wiring board 10 is employed; for example, a through-hole mounting method (pin connection) may be used as well.

As shown in FIG. 1, flex-rigid wiring board 10 is formed with first rigid substrate 11 and second rigid substrate 12 (both are rigid printed wiring boards configured to be a square with, for example, 30-mm sides) and flexible substrate 13 (a flexible printed wiring board); first rigid substrate 11 and second rigid substrate 12 face each other by sandwiching flexible substrate 13. First and second substrates 11, 12 are arranged horizontal to flexible substrate 13. Both tips of flexible substrate 13 are configured to be a “V” shape (see broken lines in FIG. 1), corresponding to first terminal rows (510a, 520a) and second terminal rows (510b, 520b). However, first and second rigid substrates 11, 12 and flexible substrate 13 are not limited to any configuration (outline); those substrates may also be shaped in other polygons such as hexagons.

If the directions of a substrate cut surface (two sides intersecting at right angles) are set as axis (X) and axis (Y) respectively, then first and second rigid substrates 11, 12 are arranged facing each other between axes (X) and (Y), specifically in a diagonal direction at an angle of 45 degrees or 135 degrees. Flexible substrate 13 sandwiched between rigid substrates 11, 12 is arranged (extended) from the connected sections with rigid substrates 11, 12 in a direction that makes angle (θ11), (θ12), (θ21) or (θ22) set at, for example, 135 degrees, with each side (the side connected to flexible substrate 13) of rigid substrates 11, 12. In doing so, the width (bus width) of flexible substrate 13 may be expanded. As a result, the number of signals may be increased.

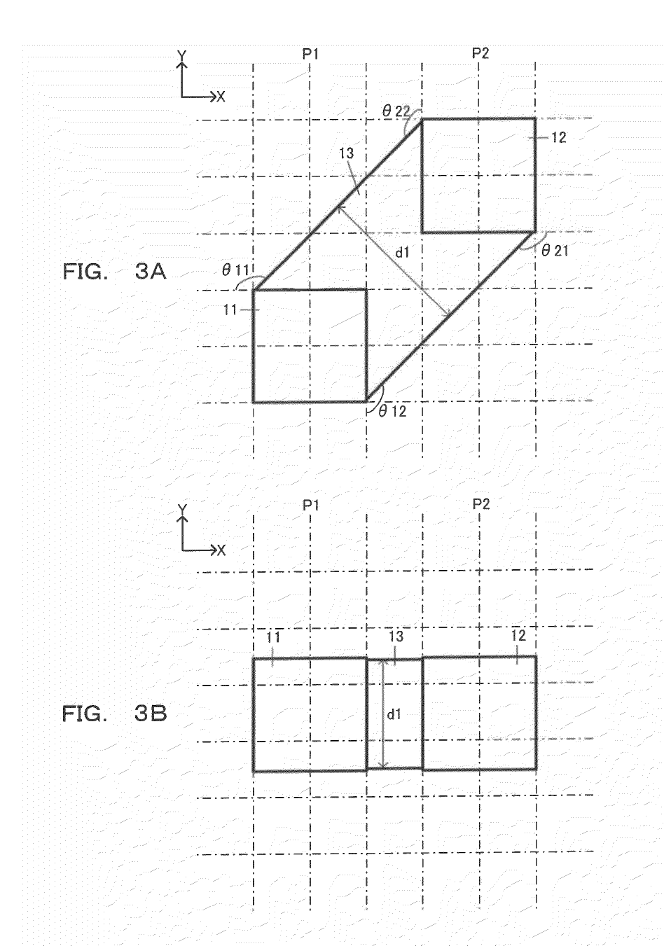

More specifically, for example, when first and second rigid substrates 11, 12 are arranged at (X) coordinates (P1, P2) as shown in FIGS. 3A, 3B, width (d1) (bus width) of flexible substrate 13 may increase if rigid substrates 11, 12 are arranged diagonally at an angle (for example, 45 degrees) to axis (X) as shown in FIG. 3A, rather than arranging rigid substrates 11, 12 along axis (X) as shown in FIG. 3B. For example, if rigid substrates 11, 12 are squares with 30-mm sides, the maximum bus width may be 30 mm in FIG. 3B; however, if arranged as shown in FIG. 3A, a bus width 1.414 times as wide may be obtained, since angles (θ11), (θ12), (θ21) and (θ22) are set at 135 degrees. By setting angles (θ11), (θ12), (θ21) and (θ22) at 135 degrees (or 45 degrees), a greater bus width may be obtained than with that of other angles.

As shown in FIG. 1, first and second rigid substrates 11, 12 have first terminal rows (510a, 520a) and second terminal rows (510b, 520b) along two sides (specifically, the sides connected to flexible substrate 13) that meet at right angles. First terminal row (510a) and second terminal row (510b) of first rigid substrate 11 are made up of multiple terminals 511; and first terminal row (520a) and second terminal row (520b) of second rigid substrate 12 are made up of multiple terminals 521. First terminal rows (510a, 520a) and second terminal rows (510b, 520b) are arranged parallel to each side (axis (X) or axis (Y)) of rigid substrates 11, 12. Therefore, the angle between the direction of such a row and the longitudinal direction (extended direction) of flexible substrate 13 is equal to the above angle (θ11), (θ12), (θ21) or (θ22) (for example, 135 degrees).

Also, on a surface of flexible substrate 13, striped wiring patterns (13a) are formed to connect the circuit patterns of first rigid substrate 11 and the circuit patterns of second rigid substrate 12. Wiring patterns (13a) have patterns that are parallel to the longitudinal direction (the direction to be connected to rigid substrates 11, 12) of flexible substrate 13. Furthermore, a connection pad (13b) is formed at each tip of wiring patterns (13a). The circuit patterns of first and second rigid substrates 11, 12 are electrically connected to each other by electrically joining connection pad (13b) to each of terminals 511, 521.

Flexible substrate 13 is connected to two sides of rigid substrates 11, 12 respectively, and has wiring patterns (13a) on its surface to be electrically connected to the terminal row (510a, 510b, 520a or 520b) on each side. As described, by connecting flexible substrate 13 to multiple sides of rigid substrates, a much greater width (bus width) of flexible substrate 13 may be obtained.

Electronic components are mounted on the surfaces of first and second rigid substrates 11, 12. Specifically, as shown in FIGS. 1 and 2, using, for example, a flip-chip connection, electronic component 501 such as a CPU is mounted on a surface of first rigid substrate 11; and electronic component 502 such as memory is mounted on a surface of second rigid substrate 12. On the surfaces of and inside first and second rigid substrates 11, 12, circuit patterns of any type are formed to be electrically connected to electronic components 501, 502. Electronic components 501, 502 are not limited to active components such as an IC circuit (for example, a graphic processor or the like); but passive components such as a resistor, capacitor or coil may be used. In addition, mounting electronic components 501, 502 is not limited to any method; for example, wire bonding may also be employed.

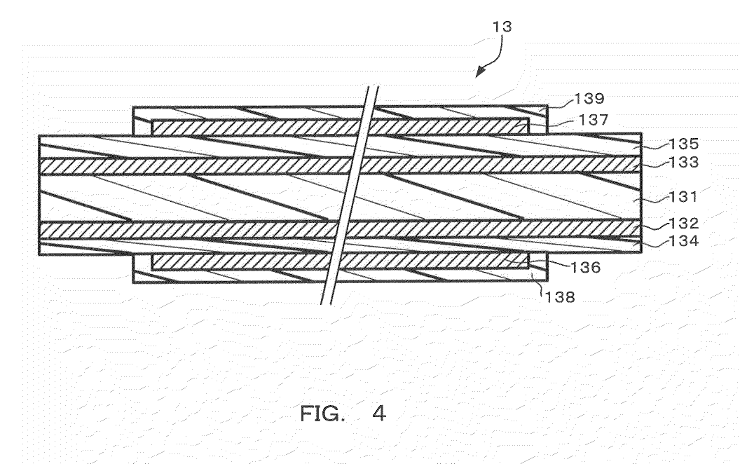

Flexible substrate 13 has, as its detailed structure shows in FIG. 4, for example, a structure made by laminating base material 131, conductive layers 132, 133, insulation films 134, 135, shield layers 136, 137 and coverlays 138, 139.

Base material 131 is formed with an insulative flexible sheet, for example, a polyimide sheet, with a thickness in the range of 20-50 μm, preferably with an approximate thickness of 30 μm.

Conductive layers 132, 133 are made, for example, of a copper pattern with an approximate thickness of 5-15 μm; they are formed on the front and back, respectively, of base material 131 to structure the above-described striped wiring patterns (13a) (FIG. 1).

Insulation films 134, 135 are made with a polyimide film or the like with an approximate thickness of 5-5 μm, and insulate conductive layers 132, 133 from the outside.

Shield layers 136, 137 are made with a conductive layer, for example, a cured silver paste film, and shield conductive layers 132, 133 from external electromagnetic noise, and shield the electromagnetic noise from conductive layers 132, 133 from going outside.

Coverlays 138, 139 are made with an insulative film such as polyimide with an approximate thickness of 5-5 μm; they insulate and protect the entire flexible substrate 13 from the outside.

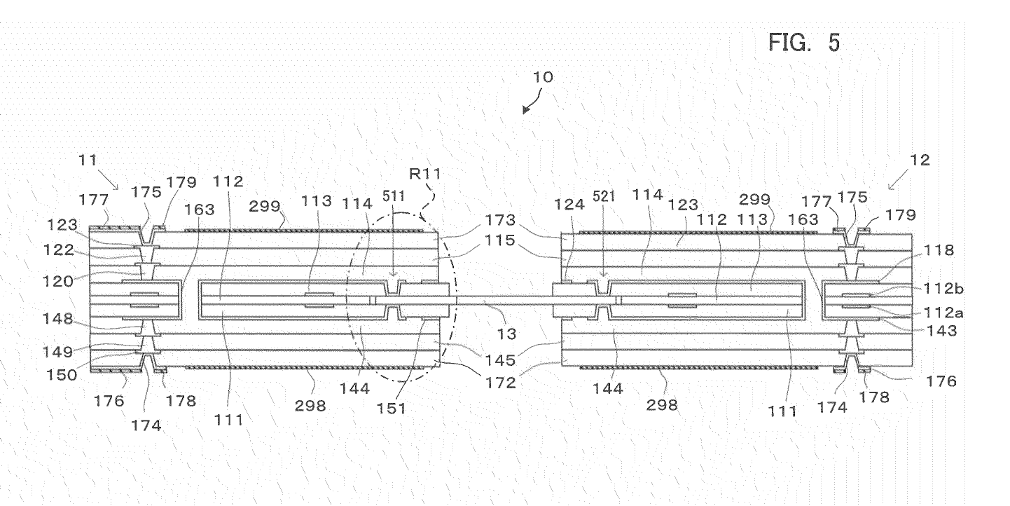

On the other hand, rigid substrates 11, 12, as is shown in FIG. 5, each are formed by laminating rigid base material 112, first and second insulation layers 111, 113, first and second upper-layer insulation layers 144, 114, third and fourth upper-layer insulation layers 145, 115, and fifth and sixth upper-layer insulation layers 172, 173.

Rigid base material 112 provides rigidity for rigid substrates 11, 12 and is formed with a rigid insulative material such as glass epoxy resin. Rigid base material 112 is arranged horizontal to flexible substrate 13 without touching it. Rigid base material 112 has substantially the same thickness as flexible substrate 13. Also, on the front and back of rigid base material 112, conductive patterns (112a, 112b) made of copper, for example, are formed respectively. Conductive patterns (112a, 112b) are each electrically connected to a further upper-layer conductor (wiring) at a predetermined spot.

First and second insulation layers 111, 113 are formed by curing a prepreg. First and second insulation layers 111, 113 each have a thickness in the range of 59-100 μm, preferably an approximate thickness of 50 μm. The prepreg is preferred to contain a resin with low-flow characteristics. Such a prepreg may be formed by impregnating a glass cloth with epoxy resin and by thermosetting the resin beforehand to advance its degree of curing. However, such a prepreg may also be made by impregnating a glass cloth with a highly viscous resin, or by impregnating a glass cloth with inorganic filler (such as silica filler), or by reducing the resin amount to be impregnated in a glass cloth.

Rigid base material 112 and first and second insulation layers 111, 113 form the core for rigid substrates 11, 12 and support rigid substrates 11, 12. In the core section, through-holes (penetrating holes) 163 are formed to electrically interconnect the conductive patterns on both surfaces (two main surfaces) of the substrate.

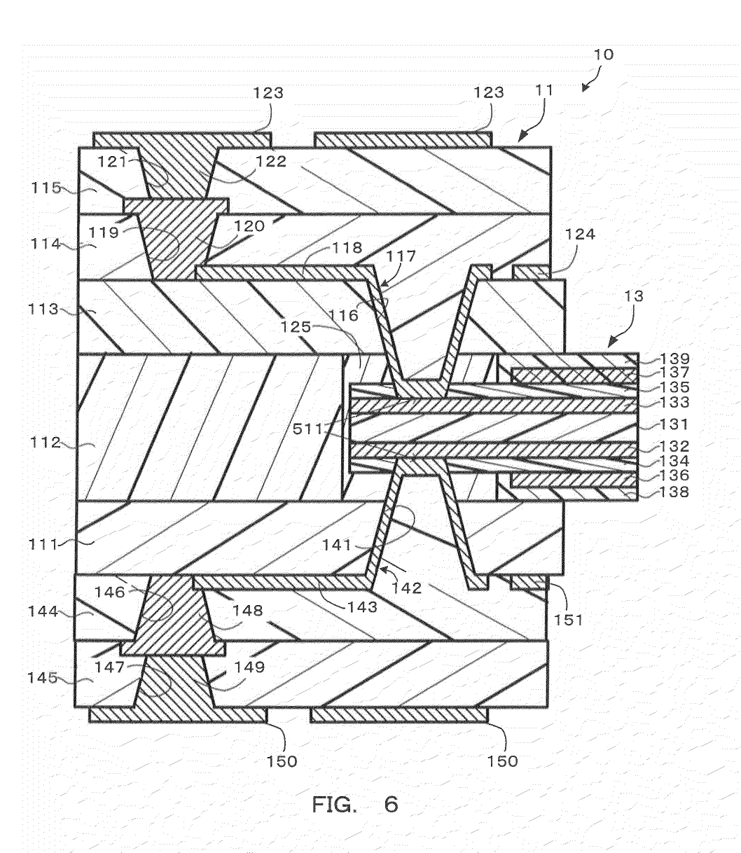

Rigid substrates 11, 12 and flexible substrate 13 are connected at the core sections of rigid substrates 11, 12 respectively. First and second insulation layers 111, 113 support and anchor flexible substrate 13 by sandwiching its tips. Specifically, as FIG. 6 shows a magnified view of region (R11) (the connected section between first rigid substrate 11 and flexible substrate 13) shown in FIG. 5, first and second insulation layers 111, 113 cover rigid base material 112 and flexible substrate 13 from both the front and back sides while exposing part of flexible substrate 13. First and second insulation layers 111, 113 are polymerized with coverlays 138, 139 formed on the surfaces of flexible substrate 13.

The structure of the connected section between rigid substrate 12 and flexible substrate 13 is the same as the structure of the connected section between rigid substrate 11 and flexible substrate 13. Therefore, only the structure at the connected section FIG. 6 between rigid substrate 11 and flexible substrate 13 is described in detail, and the detailed description of the other connected section is omitted here.

In the spaces (gaps among such members) sectioned off by rigid base material 112, flexible substrate 13 and first and second insulation layers 111, 113, resin 125 is filled as shown in FIG. 6. Resin 125 is a kind of resin, for example, that seeps from the low-flow prepreg which forms first and second insulation layers 111, 113 during the manufacturing process and is cured to be integrated with first and second insulation layers 111, 113.

At the portions of first and second insulation layers 111, 113 facing connection pads (13b) on conductive layers 132, 133 of flexible substrate 13, vias (contact holes) 141, 116 are formed respectively. From each portion of flexible substrate 13 facing vias 141, 116 (the portion where connection pad (13b) is formed as shown in FIG. 1), shield layers 136, 137 and coverlays 138, 139 of flexible substrate 13 are removed. Vias 141, 116 penetrate insulation layers 134, 135 of flexible substrate 13 respectively, and expose each connection pad (13b) formed from conductive layers 132, 133.

On each inner surface of vias 141, 116, wiring patterns (conductive layers) 142, 117 made of copper plating or the like are formed respectively. Such plated films of wiring patterns 142, 117 are connected respectively at terminals 511 to connection pads (13b) on conductive layers 132, 133 of flexible substrate 13. In vias 141, 116, resin is filled. The resin in vias 141, 116 is filled by being squeezed from the upper-layer insulation layers (upper-layer insulation layers 144, 114) by pressing, for example. Furthermore, on each top surface of first and second insulation layers 111, 113, extended patterns 143, 118, which are connected to wiring patterns 142, 117, are formed respectively. Extended patterns 143, 118 are formed with, for example, a copper-plated layer. Also, at the tips of first and second insulation layers 111, 113 on the side of flexible substrate 13, namely, in the areas of flexible substrate 13 that are positioned outside the boundary between flexible substrate 13 and rigid base material 112, conductive patterns 151, 124 insulated from the rest are arranged respectively. Heat generated in rigid substrate 11 is effectively radiated through conductive patterns 151, 124.

As described so far, in flex-rigid wiring board 10 according to the present embodiment, rigid substrates 11, 12 and flexible substrate 13 are electrically connected at each of terminals 511, 521 without using connectors. Namely, flexible substrate 13 is inserted (embedded) in rigid substrates 11, 12 respectively, and flexible substrate 13 is electrically connected to each rigid substrate at the inserted portion (embedded portion) (see FIG. 6). Accordingly, even when an impact from being dropped or the like is received, poor connection due to disconnected connectors will not occur.

Also, since part of flexible substrate 13 is embedded in rigid substrates 11, 12, rigid substrates 11, 12 adhere to and reinforce both the front and back surfaces of the portion where flexible substrate 13 and rigid substrates 11, 12 are electrically connected. Therefore, when flex-rigid wiring board 10 receives an impact from being dropped, or when stress is generated due to the different coefficients of thermal expansion (CTE) in rigid substrates 11, 12 and flexible substrate 13 caused by changes in ambient temperature, the electrical connection between flexible substrate 13 and rigid substrates 11, 12 may be maintained.

In such a sense, flex-rigid wiring board 10 is featured with a highly reliable electrical connection compared with a substrate using connectors for connection.

Also, since flexible substrate 13 is used for connection, connectors or jigs are not required to connect rigid substrates 11, 12. Accordingly, a reduction in manufacturing cost may be achieved.

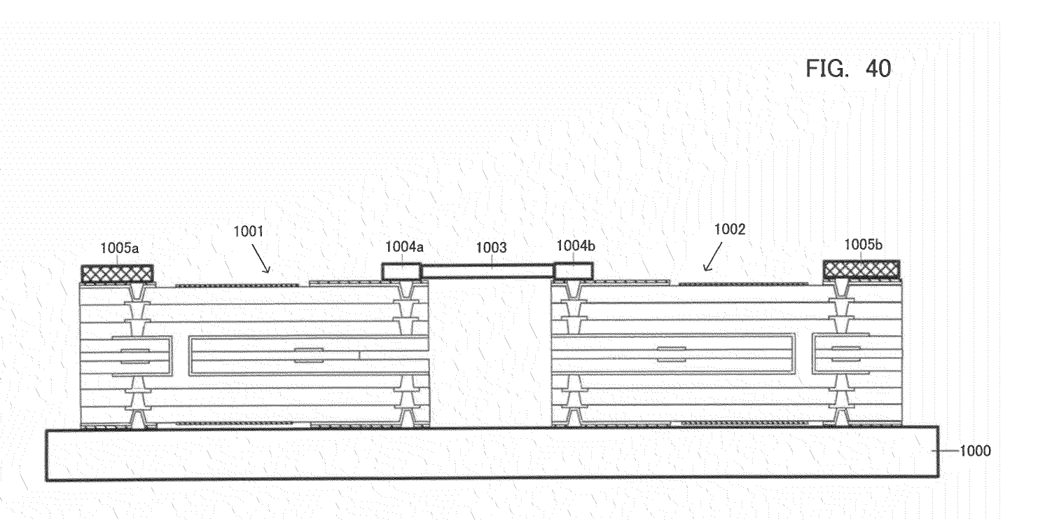

Also, flexible substrate 13 is made up partially of a flex-rigid wiring board, and part of it is embedded in rigid substrates 11, 12 respectively. Therefore, without making a substantial change in the design of rigid substrates 11, 12, substrates 11, 12 may be electrically connected to each other. Moreover, since the connection is carried out inside the substrates, larger mounting areas are secured on the surfaces of the substrates compared with the above-described mid-air highway structure (FIG. 40). Accordingly, more electronic components may be mounted.

In addition, conductive layers 132, 133 of flexible substrate 13 and wiring patterns 142, 117 of rigid substrates 11, 12 are connected through taper-shaped vias. Thus, compared with a connection by means of through-holes which extend in a direction perpendicular to the substrate surface, stresses received from impact may be dispersed and thus cracks or the like may seldom occur. Moreover, since conductive layers 132, 133 and wiring patterns 142, 117 are connected through plated films, reliability at the connected areas is high. Besides, resin is filled in vias 141, 116, further increasing connection reliability.

On the top surfaces of first and second insulation layers 111, 113, first and second upper-layer insulation layers 144, 114 are laminated respectively as shown in FIG. 6. In first and second upper-layer insulation layers 144, 114, vias (first upper-layer vias) 146, 119 connected to extended patterns 143, 118 are formed respectively. In addition, vias 146, 119 are filled respectively with conductors 148, 120 made of copper, for example. First and second upper-layer insulation layers 144, 114 are formed by curing a prepreg made, for example, by impregnating glass cloth with resin.

Furthermore, on the top surfaces of first and second upper-layer insulation layers 144, 114, third and fourth upper-layer insulation layers 145, 115 are laminated respectively. Third and fourth upper-layer insulation layers 145, 115 are also formed by curing a prepreg made, for example, by impregnating glass cloth with resin. In third and fourth upper-layer insulation layers 145, 115, vias (second upper-layer vias) 147, 121 connected to vias 146, 119 are formed respectively. Vias 147, 121 are filled respectively with conductors 149, 122 made of copper, for example. Conductors 149, 122 are electrically connected to conductors 148, 120 respectively. Accordingly, filled build-up vias are formed by vias 146, 147, 119, 121.

On the top surfaces of third and fourth upper-layer insulation layers 145, 115, conductive patterns (circuit patterns) 150, 123 are formed respectively. Then, by connecting vias 147, 121 to predetermined spots of conductive patterns 150, 123 respectively, conductive layer 133 and conductive pattern 123 are electrically connected through wiring pattern 117, extended pattern 118, conductor 120 and conductor 122; and conductive layer 132 and conductive pattern 150 are electrically connected through wiring pattern 142, extended pattern 143, conductor 148 and conductor 149.

On the top surfaces of third and fourth upper-layer insulation layers 145, 115, fifth and sixth upper-layer insulation layers 172, 173 are further laminated respectively as shown in FIG. 5. Fifth and sixth upper-layer insulation layers 172, 173 are also formed by curing a prepreg made, for example, by impregnating glass cloth with resin.

In fifth and sixth upper-layer insulation layers 172, 173, vias 174, 175 connected to vias 147, 121 are formed respectively. On the front and back of the substrate including the interiors of vias 174, 175, conductive patterns 176, 177 made of copper, for example, are formed respectively. Conductive patterns 176, 177 are electrically connected to conductors 149, 122 respectively. Moreover, on the front and back of the substrate, patterned solder resists 298, 299 are formed respectively. Electrodes 178, 179 (board connection terminals and component connection terminals) are formed, for example, by chemical gold plating at each predetermined spot of conductive patterns 176, 177. Such connection terminals are arranged on both surfaces of first and second rigid substrates 11, 12 respectively.

Then, by mounting flex-rigid wiring board 10 on a surface of motherboard 100, which is a rigid substrate, an electronic device is formed. Since such an electronic device is reinforced by flexible substrate 13 on the side of flex-rigid wiring board 10, even when an impact is received from being dropped or the like, such an impact is reduced on the side of motherboard 100. Thus, cracks or the like may seldom occur in motherboard 100.

In flex-rigid wiring board 10, as shown in FIGS. 2, 5 and 6, for example, electronic components 501, 502 are electrically connected to each other through signal lines formed with the conductors in flex-rigid wiring board 10 (wiring patterns 117, 142, extended patterns 118, 143, conductors 120, 122, 148, 149, conductive patterns 123, 124, 150, 151, 176, 177, conductive layers 132, 133 and so forth). Those signal lines allow mutual signal transmission. Those signal lines electrically connect electronic component 501 and electronic component 502 using routes that avoid through-holes 163. Accordingly, signals between electronic components 501, 502 are transmitted only along the front side of the substrate (outside the boundaries of the core, on the side of rigid substrates 11, 12 where the electronic components are mounted); signals are not transmitted from the front side to the back side (outside the boundaries of the core, on the side where motherboard 100 is positioned). Namely, for example, signals from electronic component 502 (memory) are transmitted to electronic component 501 (CPU with a logic operation function) through, for example, as arrows (L1) show in FIG. 2, conductors 122, 120, extended pattern 118, wiring pattern 117, conductive layer 133, wiring pattern 117, extended pattern 118 and conductors 120, 122 in that order (see FIGS. 5 and 6 for detail). By making such a structure, the route for signal transmission between electronic components is made shorter without detouring to motherboard 100. By shortening the signal transmission route, its capacity for paratisism or the like may be reduced. Accordingly, high-speed signal transmission between electronic components may be achieved. Also, by shortening the signal transmission route, noise contained in the signal is reduced.

On the other hand, a power source for electronic components 501, 502 is supplied from motherboard 100. Namely, the conductors in flex-rigid wiring board 10 form power-source lines to supply a power source from motherboard 100 to each of electronic components 501, 502. The power-source lines provide a power source for each of electronic components 501, 502 by routes through conductors 149, 148, through-hole 163 and conductors 120, 122 (see FIG. 5 for detail), as arrows (L2) show in FIG. 2, for example. In so structuring, while a required power source is provided for each of electronic components 501, 502, high-speed signal transmission between electronic components 501, 502 may be achieved.

When manufacturing flex-rigid wiring board 10, flexible substrate 13 (FIG. 4) is manufactured first. Specifically, a copper film is formed on both surfaces of polyimide base material 131 prepared to be a predetermined size. In the following, by patterning the copper films, conductive layers 132, 133 are formed that have wiring patterns (13a) and connection pads (13b) (FIG. 1). Then, on each surface of conductive layers 132, 133, insulation films 134, 135 made of polyimide, for example, are formed through a laminating process. Furthermore, after silver paste is applied on insulation films 134, 135 except for the tips of flexible substrate 13, the silver paste is cured to form shield layers 136, 137. Then, coverlays 138, 139 are formed to cover each surface of shield layers 136, 137. Here, shield layers 136, 137 and coverlays 138, 139 are formed to avoid connection pads (13b).

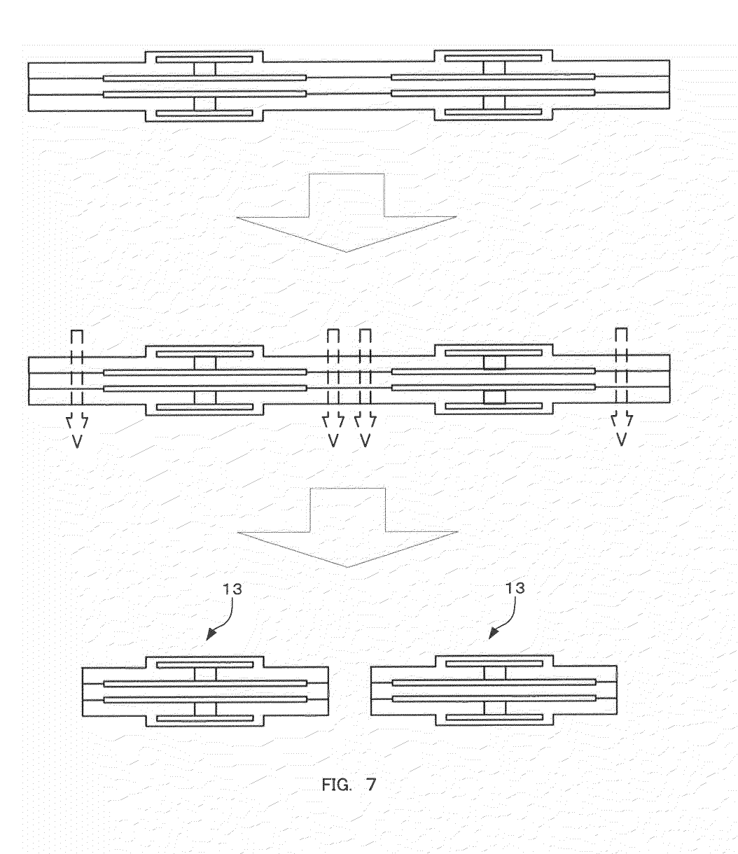

Through such a series of steps, a wafer having a laminated structure shown in FIG. 4 is completed. Such a wafer is a material commonly used for multiple products. Namely, as shown in FIG. 7, by cutting the wafer into a predetermined size and configuration using a laser or the like, flexible substrate 13 of a predetermined size and configuration is obtained. During that time, according to requirements, the outline of flexible substrate 13 is configured to correspond to those of first terminal rows (510a, 520a) and second terminal rows (510b, 520b) (see broken lines in FIG. 1).

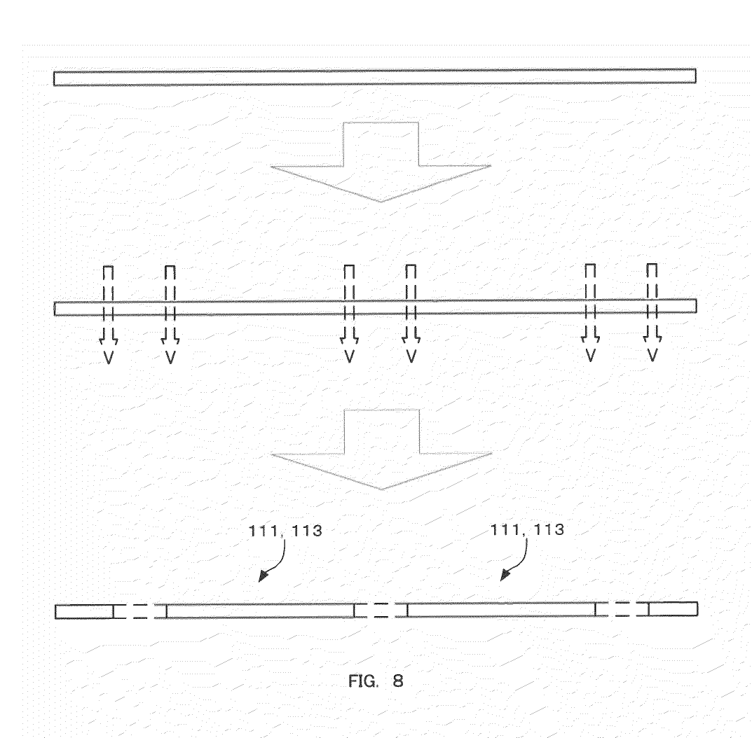

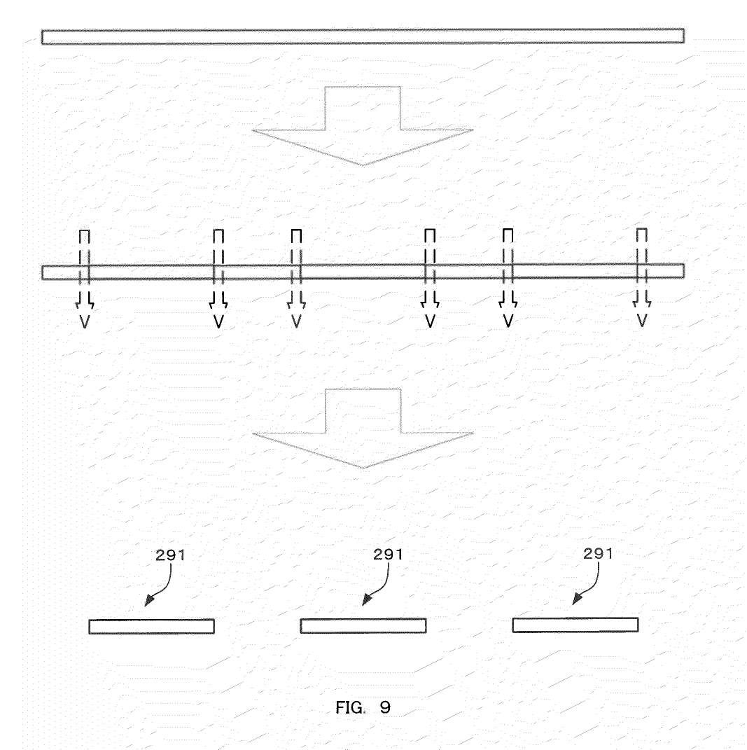

Next, flexible substrate 13 as manufactured above is joined with each rigid substrate of first and second rigid substrates 11, 12. Before joining flexible substrate 13 and rigid substrates 11, 12, as shown in FIG. 8, for example, first and second insulation layers 111, 113 of a predetermined size are prepared by cutting a wafer commonly used for multiple products using a laser or the like. Also, as shown in FIG. 9, for example, separators 291 of a predetermined size are prepared by cutting a wafer commonly used for multiple products by a laser or the like.

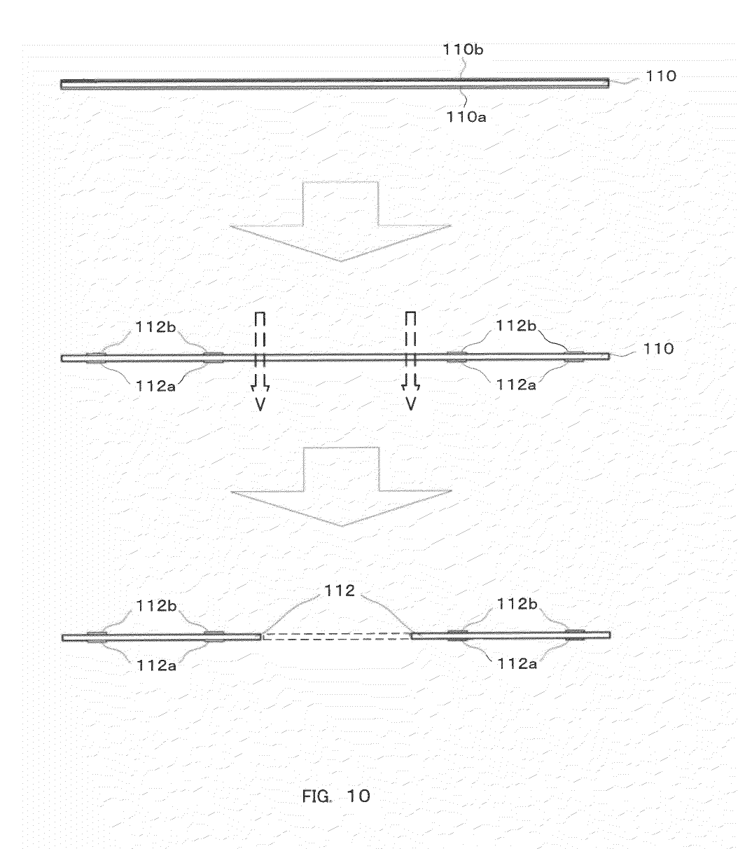

Also, rigid base material 112 that makes the core for rigid substrates 11, 12 is produced from wafer 110 commonly used for multiple products as shown in, for example, FIG. 10. Namely, after conductive films (l 10a, 110b) made of copper, for example, are formed on the front and back of wafer 110 respectively, conductive films (110a, 110b) are patterned to form conductive patterns (112a, 112b) through, for example, a predetermined lithography process (pretreatment, laminating, exposing to light, developing, etching, removing the film, inspecting inner layers and so forth). Then, using a laser or the like, a predetermined portion of wafer 110 is removed to obtain rigid base materials 112 for rigid substrates 11, 12. After that, the surfaces of the conductive patterns of rigid base material 112 as manufactured above are treated to make them roughened.

Rigid base material 112 is formed, for example, with glass-epoxy base material of a thickness in the range of 59-150 μm, preferably an approximate thickness of 100 μm; first and second insulation layers 111, 113 are formed, for example, with a prepreg of a thickness in the range of 20-50 μm. Separator 291 is formed, for example, with a cured prepreg or polyimide film or the like. The thicknesses of first and second insulation layers 111, 113 are set substantially the same so as to make, for example, a symmetrical structure on the front and back of rigid substrates 11, 12. The thickness of separator 291 is set to be substantially the same as that of second insulation layer 113. Also, the thickness of rigid base material 112 and the thickness of flexible substrate 13 are preferred to be made substantially the same. By doing so, resin 125 will be filled in spaces formed between rigid base material 112 and coverlays 138, 139. Accordingly, flexible substrate 13 and rigid base material 112 may be joined more securely.

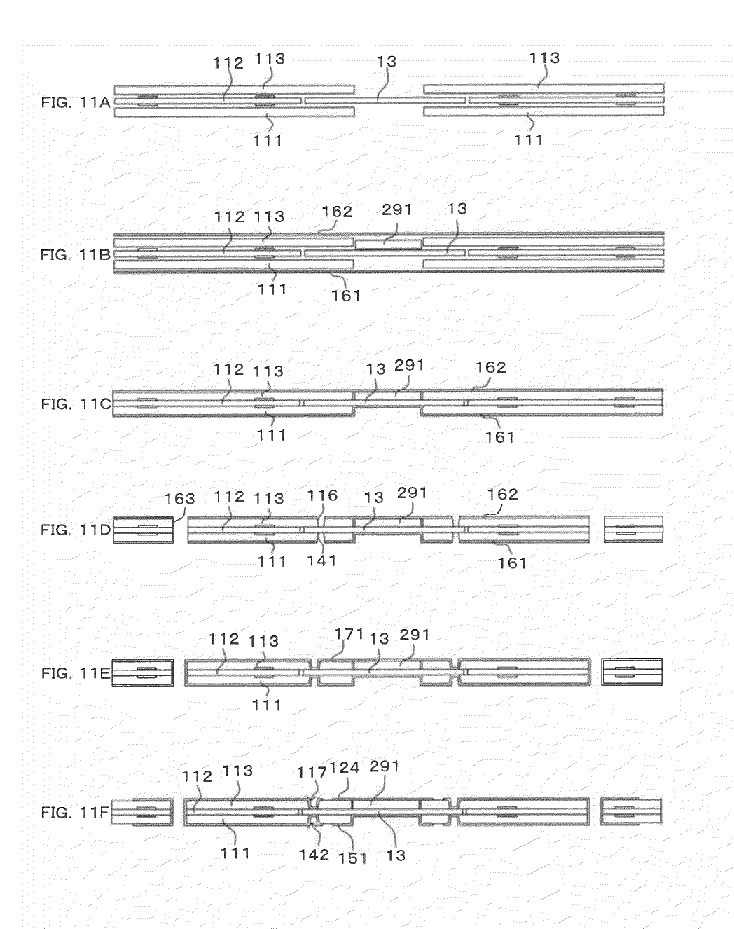

In the following, first and second insulation layers 111, 113, rigid base materials 112 and flexible substrate 13 that were cut in the process shown in FIGS. 7, 8 and 10 are aligned and arranged, for example, as shown in FIG. 11A. During that time, each tip of flexible substrate 13 is sandwiched between first and second insulation layers 111, 113 and then aligned.

Furthermore, as shown in FIG. 11B, for example, separator 291 that was cut in the step shown in FIG. 9 is arranged side by side with second insulation layer 113 on one surface (for example, the upper surface) of flexible substrate 13 which is exposed between rigid substrate 11 and rigid substrate 12. Then, conductive films 161, 162 made of copper, for example, are disposed on the outside (both front and back). Separator 291 is secured using, for example, an adhesive agent. By making such a structure, since separator 291 supports conductive film 162, problems, such as broken copper foil caused by a plating solution that seeps into the space between flexible substrate 13 and conductive film 162, may be prevented or suppressed.

Next, the structure, as so aligned (FIG. 11B), is pressure-pressed as shown, for example, in FIG. 11C. During that time, resin 125 is squeezed from each prepreg that forms first and second insulation layers 111, 113. As shown in FIG. 6, the space between rigid base material 112 and flexible substrate 13 is filled by resin 125. As such, by filling the space with resin 125, flexible substrate 13 and rigid base material 112 are adhered securely. Such pressure-pressing is conducted using, for example, hydraulic pressing equipment, under the approximate conditions of temperature at 200° C., pressure at 40 kgf and pressing time of three hours.

In the following, the entire structure is heated or the like, and the prepreg forming first and second insulation layers 111, 113 and resin 125 are cured and integrated. At that time, coverlays 138, 139 (FIG. 6) of flexible substrate 13 and the resin in first and second insulation layers 111, 113 are polymerized. By polymerizing the resin of insulation layers 111, 113, the surroundings of vias 141, 116 (they will be formed in a later process) are secured with resin, thus enhancing connection reliability of each connection section between vias 141 and conductive layer 132 (or between vias 116 and conductive layer 133).

Next, after a predetermined pretreatment, for example, a CO₂ laser, for example, is beamed using CO₂ laser processing equipment to form through-holes 163 as shown in FIG. 11D. During that time, vias 116, 141 (for example, IVHs (Interstitial Via Holes)) are also formed to connect conductive layers 132, 133 of flexible substrate 13 (FIG. 6) and rigid substrates 11, 12 respectively.

In the following, after conducting desmear treatment (removing smears) and soft etching, for example, as shown in FIG. 11E, PN plating (for example, chemical copper plating and electrical copper plating) is performed to plate copper on the entire surfaces of the structure. The copper from such copper plating and already existing conductive films 161, 162 are integrated to form copper films 171 on the entire surfaces of the substrate including the interiors of vias 116, 141 and the interiors of through-holes 163. During that time, since flexible substrate 13 is covered by conductive films 161, 162, it is not directly exposed to the plating solution. Therefore, flexible substrate 13 will not be damaged by the plating solution.

In the following, copper films 171 on the surfaces of the substrate are patterned, for example, as shown in FIG. 11F, through a predetermined lithography process (pretreatment, laminating, exposing to light, developing, etching, removing the film, inspecting inner layers and so forth). By doing so, wiring patterns 142, 117 and extended patterns 143, 118 are formed to be connected to conductive layers 132, 133 of flexible substrate 13 (FIG. 6) respectively along with conductive patterns 151, 124. At that time, copper foil is kept on each tip of first and second insulation layers 111, 113 on the side of flexible substrate 13. After that, the copper film surfaces are treated to make them roughened.

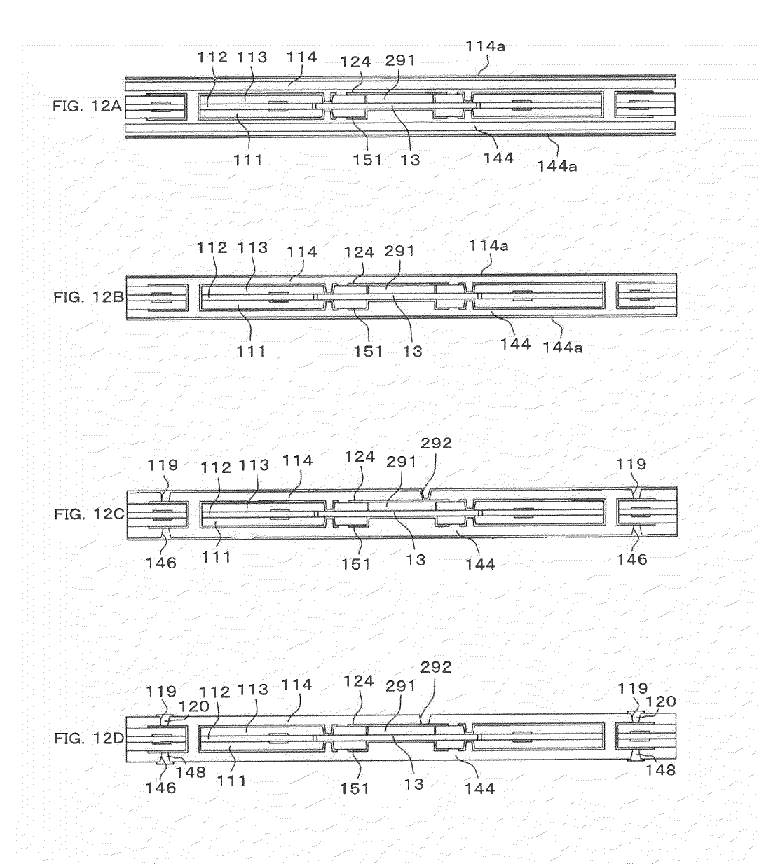

In the following, as shown in FIG. 12A, for example, on the front and back of the resultant structure, first and second upper-layer insulation layers 144, 114 are disposed respectively. Then, conductive films (114a, 144a) made of copper, for example, are further disposed outside those layers. After that, as shown in FIG. 12B, the structure is pressure-pressed. At that time, vias 116, 141 are filled with the resin squeezed from the prepreg each forming first and second upper-layer insulation layers 114, 144. Then, the prepreg and the resin in the vias are set through thermal treatment or the like to cure first and second upper-layer insulation layers 144, 114.

In the following, conductive films (114a, 144a) are made thinner to a predetermined thickness by half etching, for example. Then, after a predetermined pretreatment, using a laser, for example, vias 146 are formed in first upper-layer insulation layer 144, and vias 119 and cutoff line 292 are formed in second upper-layer insulation layer 114. Then, after conducting desmear treatment (removing smears) and soft etching, for example, as shown in FIG. 12C, conductors are formed in the interiors of vias 146, 119 and cutoff line 292 through PN plating (for example, chemical copper plating and electrical copper plating). Such conductors may also be formed by printing conductive paste (for example, thermosetting resin containing conductive particles) by screen printing.

In the following, the conductive films on the surfaces of the substrate are made thinner to a predetermined thickness by half etching, for example. Then, the conductive films on the surfaces of the substrate are patterned through, for example, a predetermined lithography process (pretreatment, laminating, exposing to light, developing, etching, removing the film, inspecting inner layers and so forth) as shown in FIG. 12D. By doing so, conductors 148, 120 are formed. Also, the conductor in cutoff line 292 is removed by etching. Then, the surfaces of the conductors are treated to make them roughened.

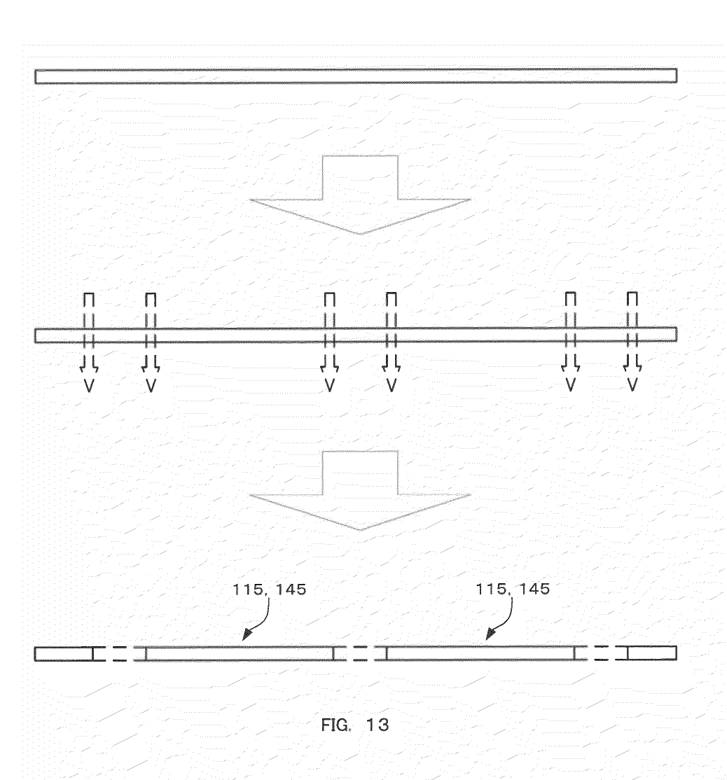

Here, before describing the next process, a step conducted prior to such process is described. Namely, prior to the next process, as shown in FIG. 13, a wafer used commonly for multiple products is cut using a laser or the like, for example, to form third and fourth upper-layer insulation layers 145, 115 of a predetermined size.

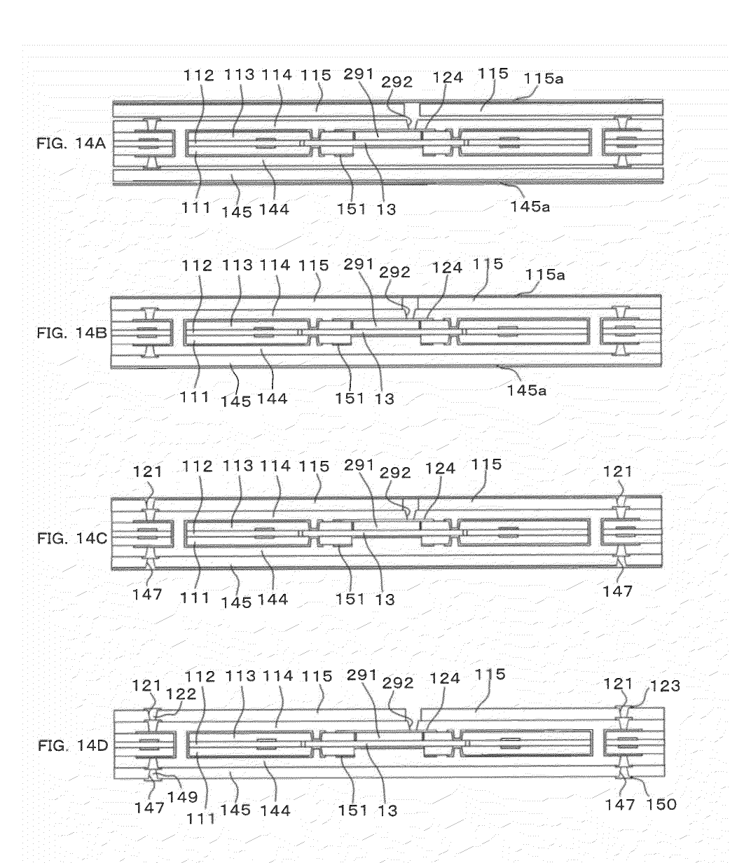

Then, in the following process, as shown in FIG. 14A, on the front and back of the substrate, third and fourth upper-layer insulation layers 145, 115, which were cut in the process shown in FIG. 13, are disposed. Then, on their outside (on both front and back), conductive films (145a, 115a) made of copper, for example, are disposed. As shown in FIG. 14A, fourth upper-layer insulation layer 115 is disposed, leaving a gap over cutoff line 292. After that, by heating or the like, third and fourth upper-layer insulation layers 145, 115 are cured. Third and fourth upper-layer insulation layers 145, 115 are each formed with a regular prepreg made, for example, by impregnating glass cloth with resin.

In the following, the resultant structure is pressed as shown in FIG. 14B. After that, conductive films (145a, 115a) are each made thinner to a predetermined thickness by half etching, for example. Then, after conducting pretreatment, vias 147, 121 are formed in third and fourth upper-layer insulation layers 145, 115 respectively using a laser, for example. After conducting a desmear process (removing smears) and soft etching, vias 147, 121 are filled with conductor, for example, as shown in FIG. 14C, through PN plating (for example, chemical copper plating and electrical copper plating). In doing so, by filling the interiors of vias 147, 121 with the same conductive paste material, connection reliability may be enhanced when thermal stresses are exerted on vias 147, 121. The conductor may also be formed by printing conductive paste (such as thermosetting resin containing conductive particles) by, for example, screen printing.

In the following, as shown in FIG. 14D, conductive films on the substrate surfaces are made thinner to a predetermined thickness by half etching, for example. After that, the copper films on the substrate surfaces are patterned, for example, through a predetermined lithography process (pretreatment, laminating, exposing to light, developing, etching, removing the film, inspecting inner layers and so forth). In doing so, conductors 149, 122 and conductive patterns 150, 123 are formed. Then, the surfaces of the conductors are treated to make them roughened.

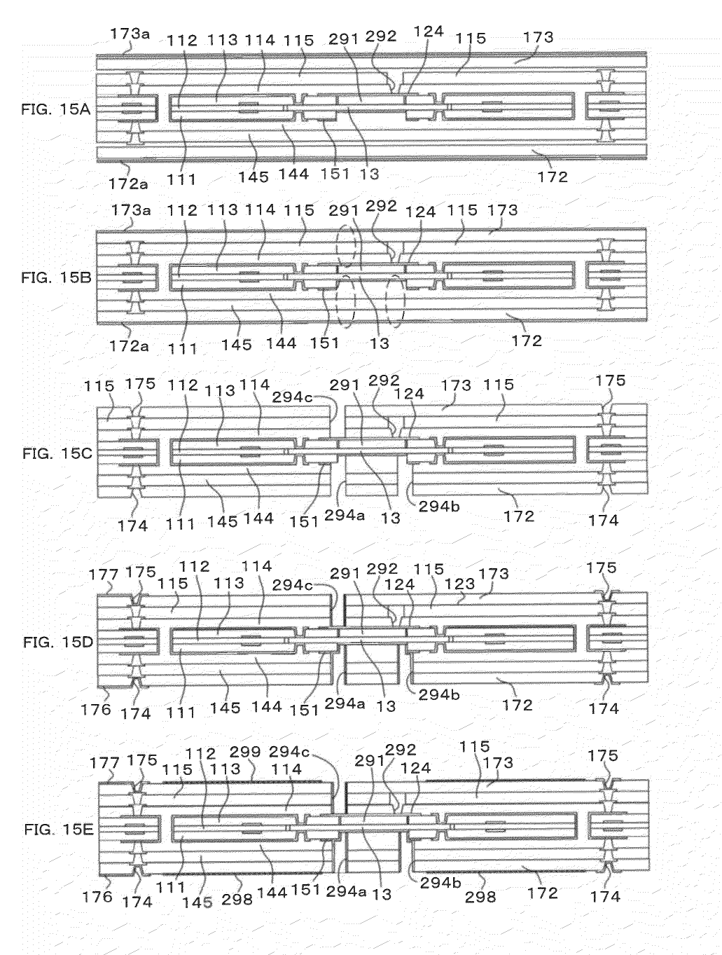

Next, as shown in FIG. 15A, fifth and sixth upper-layer insulation layers 172, 173 are disposed on the front and back of the resultant structure, then on its outside (on both front and back), conductive films (172a, 173a) made of copper, for example, are disposed. Fifth and sixth upper-layer insulation layers 172, 173 are formed, for example, with a prepreg made by impregnating glass cloth with resin.

In the following, the structure is pressed as shown in FIG. 15B. After that, conductive films (172a, 173a) are made thinner to a predetermined thickness by half etching, for example. Then, after conducting a predetermined pretreatment, vias 174, 175 are formed respectively in fifth and sixth upper-layer insulation layers 172, 173 by laser beams or the like. Also, as shown in FIG. 15C, the insulation layer in each portion indicated by the broken lines in FIG. 15B, namely, the insulation layer at the edges of separator 291 (the border portions between second insulation layer (113) and separator 291), is removed, and cutoff lines (notches) (294a-294c) are formed. At that time, cutoff lines (294a-294c) are formed (cut) using, for example, conductive patterns 151, 124 as a stopper. During that time, the energy or beam time may be adjusted so that a certain amount of conductive patterns 151, 124, which are used as a stopper, will be cut.

In the following, by performing PN plating (for example, chemical copper plating and electrical copper plating), conductors are formed on the entire surfaces of the substrate including the interiors of vias 174, 175. Then, the copper foils on the substrate surfaces are made thinner to a predetermined thickness by half etching, for example. After that, the copper foils on the substrate surfaces are patterned, for example, through a predetermined lithography process (pretreatment, laminating, exposing to light, developing, etching, removing the film and so forth). In doing so, conductive patterns 176, 177 are formed as shown in FIG. 15D. After forming the conductive patterns, those patterns are inspected.

In the following, solder resists are formed on the entire surfaces of the substrate by screen printing, for example. Then, as shown in FIG. 15E, the solder resists are patterned through a predetermined lithography process. After that, patterned solder resists 298, 299 are set, for example, by heating or the like.

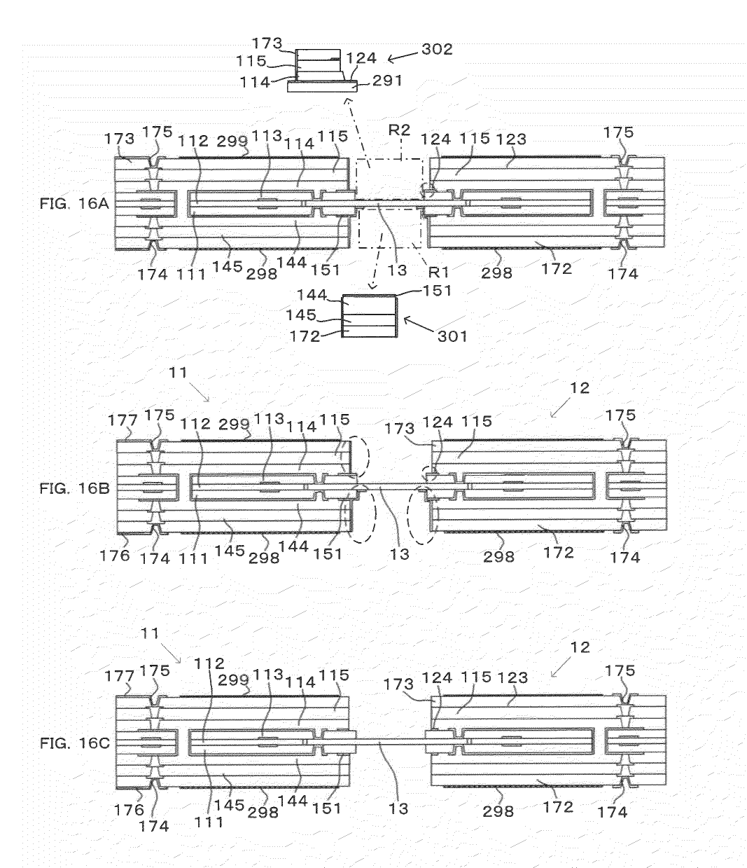

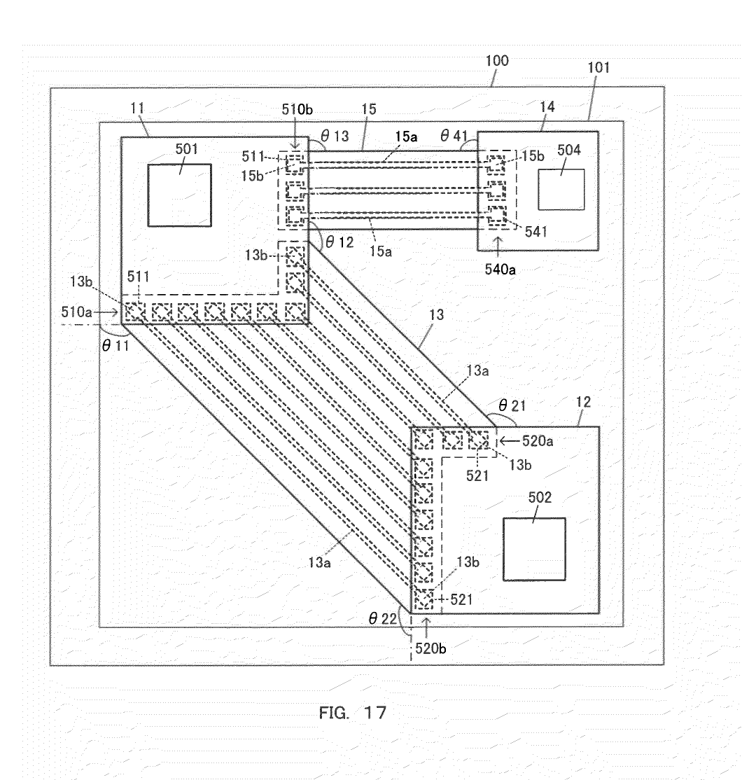

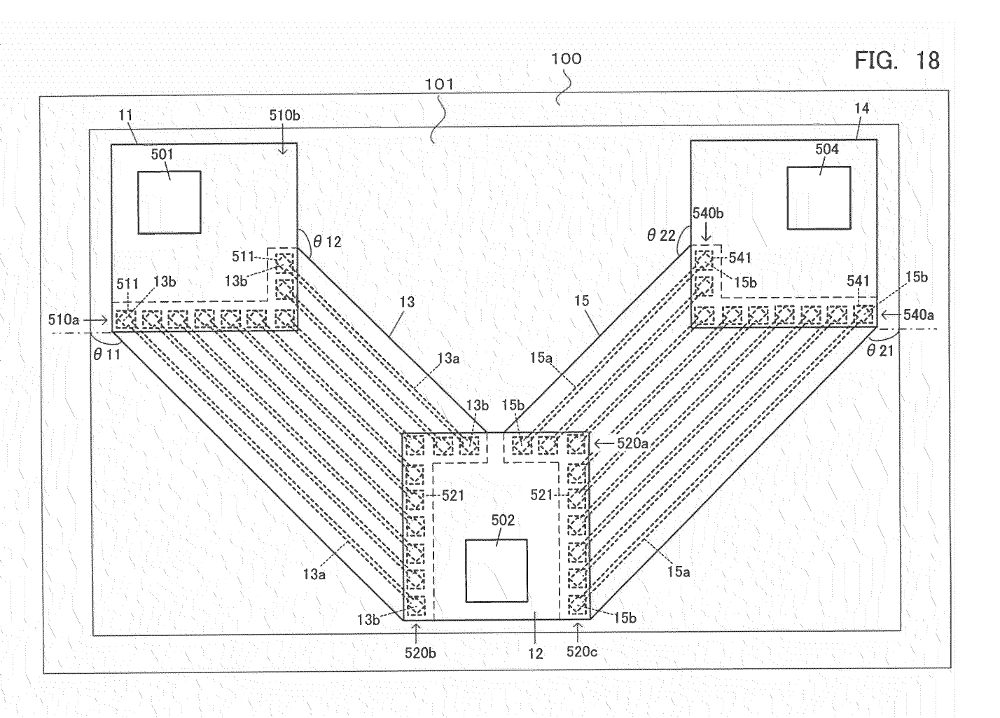

In the following, after drilling and outline processing are conducted around the edges of separator 291 (see broken lines in FIG. 15B), structures 301, 302 are removed by tearing them off from flexible substrate 13 as shown in FIG. 16A. During that time, separation is easily done because of separator 291. Also, when structures 301, 302 are separated (removed) from the rest, since conductive pattern 151 is not adhered, but is only pressed onto coverlay 138 of flexible substrate 13 (see FIG. 11C), part of conductive pattern 151 (the area in contact with flexible substrate 13) is also removed along with structures 301, 302.

As described, by exposing the center portion of flexible substrate 13, spaces (regions (R1, R2)) which allow flexible substrate 13 to warp (bend) are formed on the front and back (in the direction where insulation layers are laminated) of flexible substrate 13. By doing so, flex-rigid wiring board 10 may be bent or the like at those portions of flexible substrate 13.

At the tip of each insulation layer facing the removed areas (region (R1, R2)), conductive patterns 124, 151 remain as shown, for example, in broken lines in FIG. 16B. The remaining copper is removed according to requirements by, for example, mask etching (pretreatment, laminating, exposing to light, developing, etching, removing the film and so forth) as shown in FIG. 16C.

Accordingly, flexible substrate 13 and rigid substrates 11, 12 are connected. In the following, electrodes 178, 179 are formed by chemical gold plating, for example. After that, through outline processing, warp correction, conductivity testing, exterior inspection and final inspection, flex-rigid wiring board 10 is completed as shown earlier in FIG. 5. As described above, flex-rigid wiring board 10 has a structure in which the tips of flexible substrate 13 are sandwiched between the core sections (first and second insulation layers 111, 113) of the rigid substrates, and lands of rigid substrates 11, 12 and connection pads of the flexible substrate are connected respectively through plated films.

On flex-rigid wiring board 10, specifically on each surface of rigid substrates 11, 12, electronic components 501, 502 are mounted respectively. After the board is sealed in packaging 101 as shown earlier in FIG. 2, and mounted on motherboard 100, an electronic device according to an embodiment of the present invention is completed.

In the above, a flex-rigid wiring board and an electronic device according to an embodiment of the present invention were described. However, the present invention is not limited to such an embodiment.

Three or more rigid substrates may also be connected. For example, as shown in FIG. 17, using two flexible substrates 13, 15, first rigid substrate 11 with a mounted CPU (electronic component 501) may be electrically connected to second and third rigid substrates 12, 14 with mounted memory and graphic processor (electronic components 502, 504) respectively. In the example shown in FIG. 17, first rigid substrate 11 and second rigid substrate 12 are connected diagonally by sandwiching flexible substrate 13 that extends in a direction with angle (θ11), (θ12), (θ21) or (θ22) set at 135 degrees, the same as in the above embodiment. However, part of second terminal row (510b) is allotted for connection to third rigid substrate 14; namely, terminals 511 of second terminal row (510b) are electrically connected to terminals 541 (terminal row (540a)) of rigid substrate 14 by means of wiring patterns (15a) with connection pads (15b) at both tips of flexible substrate 15. First rigid substrate 11 and third rigid substrate 14 are connected straight in the direction of axis (X) (see FIGS. 3A and 3B) by sandwiching flexible substrate 15, which extends in a direction that makes angle (θ13) or (θ41) set at 90 degrees with a side of each substrate (the side connected to flexible substrate 15).

In the example shown in FIG. 17, by diagonally connecting flexible substrate 13 to first rigid substrate 11, rigid substrates 11, 12, which are positioned diagonally, are directly connected (not through rigid substrate 14). By directly connecting rigid substrates 11, 12, the distance between the CPU (electronic component 501) and memory (electronic component 502) is reduced, thus the communication speed between such electronic components may be increased.

Also, as shown in FIG. 18, third rigid substrate 14 may be diagonally connected the same as in rigid substrates 11, 12. In the example shown in FIG. 18, first to third terminal rows (520a-520c) are arranged on three sides of second rigid substrate 12. Then, part of first terminal row (520a) and second terminal row (520b) of second rigid substrate 12 are diagonally connected to first and second terminal rows (510a, 510b) of first rigid substrate 11; and part (the rest) of first terminal row (520a) and third terminal row (520c) of second rigid substrate 12 are diagonally connected to first and second terminal rows (540a, 540b) of third rigid substrate 14.

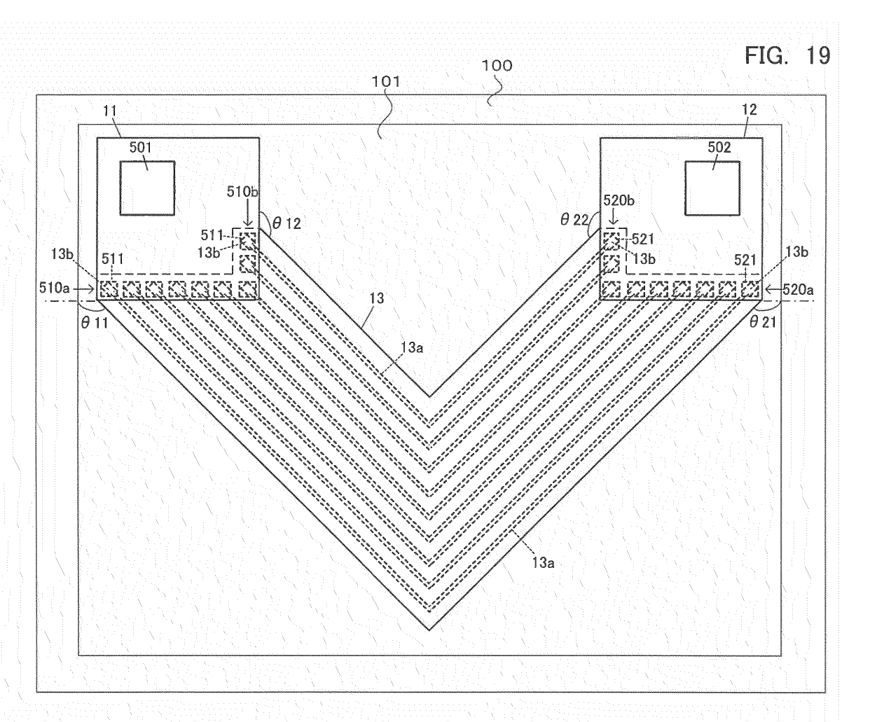

As shown in FIG. 19, to connect rigid substrates 11, 12 arranged in the direction of axis (X) (see FIG. 3B), flexible substrate 13, which is diagonally connected to each substrate, may be used. In the example shown in FIG. 19, rigid substrates 11, 12 are connected by means of flexible substrate 13 which is bent to be V-shaped. Angles (θ11), (θ12), (θ21) and (θ22) are set at 135 degrees, for example. In such a structure, the width (bus width) of flexible substrate 13 may also be expanded. As a result, the number of signals may be increased.

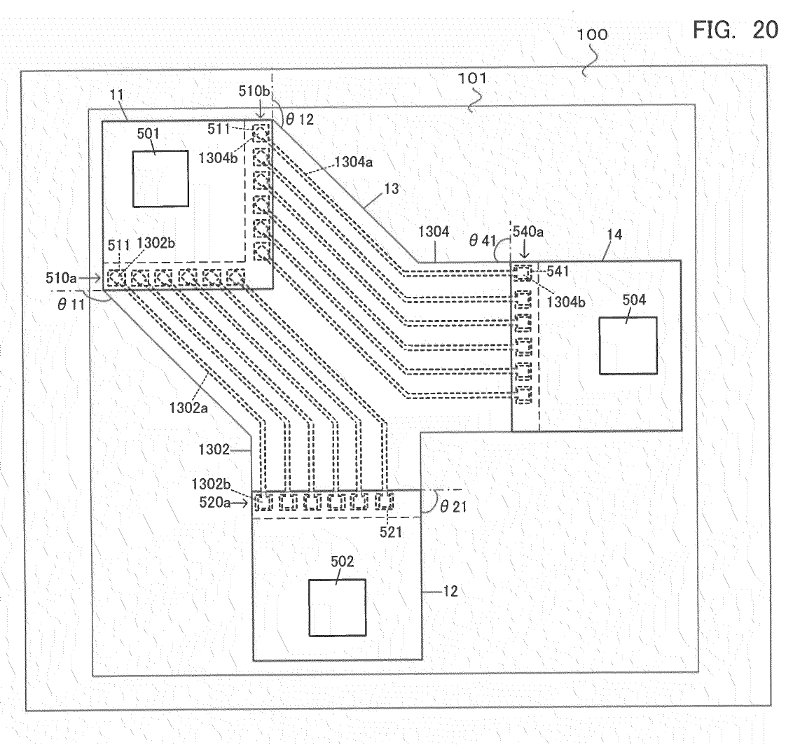

Without using multiple flexible substrates, one flexible substrate with a fork may also be used to electrically connect three or more rigid substrates. For example, as shown in FIG. 20, using flexible substrate 13, which branches off at a fork to form bifurcated routes 1302, 1304, first to third rigid substrates 11, 12, 14 may be electrically connected. In the example shown in FIG. 20, a tip of flexible substrate 13 (the portion before splitting) is diagonally connected to rigid substrate 11 (angles (θ11, θ12)=135°); and bifurcated routes 1302, 1304 are connected straight (angles (θ21, θ41)=90°) to rigid substrates 12, 14. Through wiring patterns (1302a) with connection pads (1302b) at both tips of bifurcated route 1302, first terminal row (510a) (of first rigid substrate 11) and terminal row (520a) (of second rigid substrate 12) are electrically connected; and through wiring patterns (1304a) with connection pads (1304b) at both tips of bifurcated route 1304, second terminal row (510b) (of first rigid substrate 11) and terminal row (540a) (of third rigid substrate 14) are electrically connected.

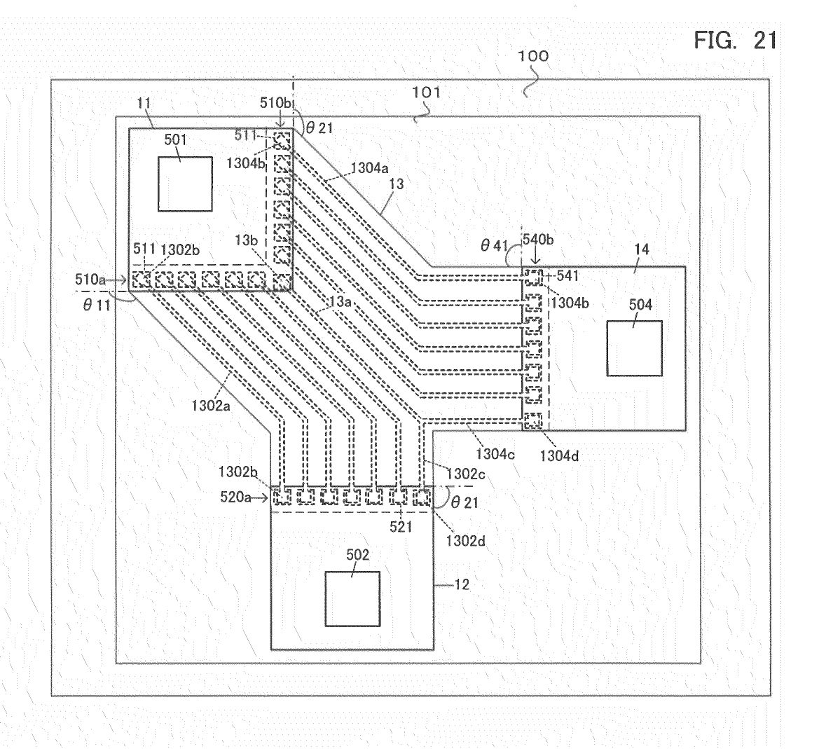

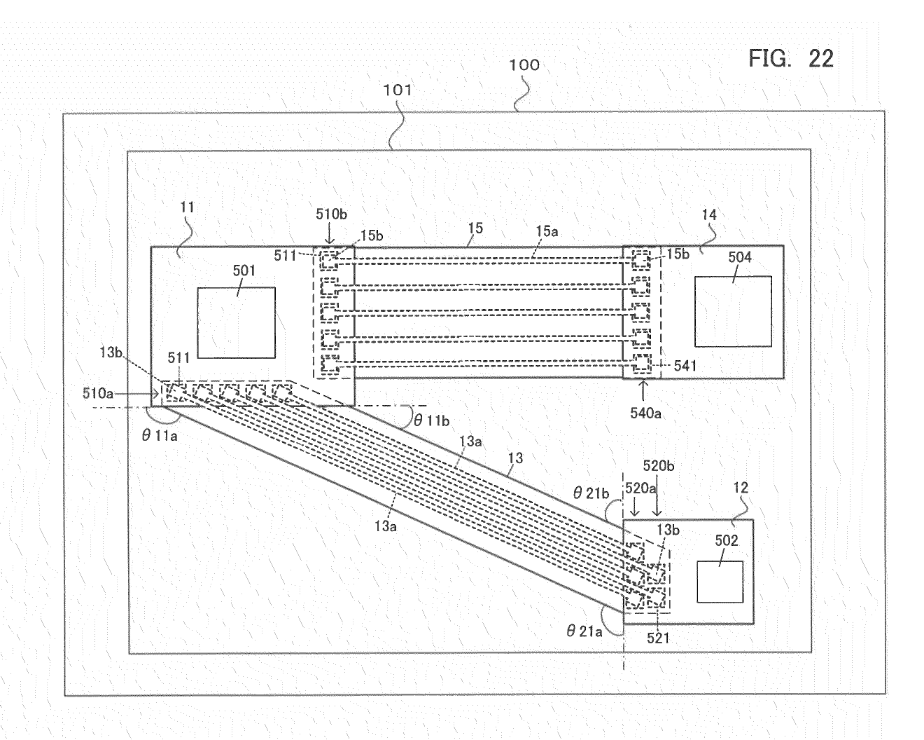

Also, in such a case, as shown in FIG. 21, common wiring to second and third rigid substrates 12, 14 may be bifurcated according to the forked shape of flexible substrate 13 so that a tip (a portion before the split) of wiring pattern (13a) is connected to terminal 511 (of first rigid substrate 11) by means of connection pad (13b), and bifurcated wiring routes (1302c, 1304c) are connected respectively to terminals 521, 541 (of second and third rigid substrates 12, 14) by means of connection pads (1302d, 1304d).

In the above embodiment, examples were shown in which a flexible substrate was diagonally connected to two sides of a rigid substrate. However, the present invention is not limited to such, but an effect to expand the above-mentioned bus width may also be achieved in an example in which a flexible substrate diagonally connects to only one side of a rigid substrate.

For example, as shown in FIG. 22, the width (bus width) of flexible substrate 13 may be expanded by connecting flexible substrate 13 and rigid substrates 11, 12 with angles (θ11a), (θ11b), (θ21a) and (θ21b) (the angles between the connected sides of rigid substrates 11, 12 and flexible substrate 13) set to be acute or obtuse. In the example shown in FIG. 22, angles (θ11a) and (θ21a) are set at 150 degrees, and (θ11b) and (θ21b) are set at 30 degrees. Also, to correspond to the narrowed spaces in wiring patterns (13a) of flexible substrate 13, two terminal rows of rigid substrate 12 (terminal rows (520a, 520b)) are arranged.

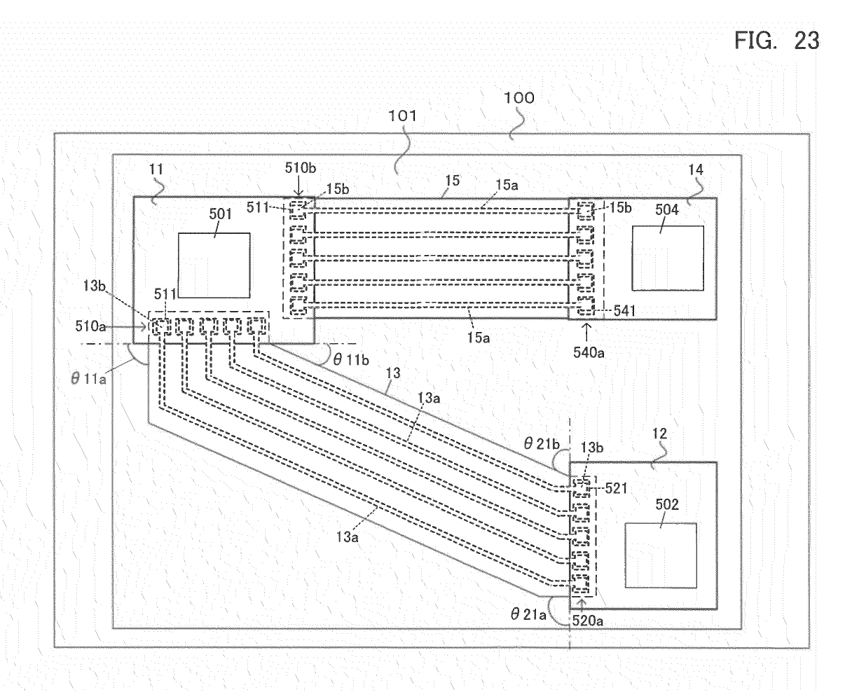

Also, for example, as shown in FIG. 23, angles (θ11a) and (θ21a) may be set at 90 degrees so that the spaces in wiring patterns (13a) of flexible substrate 13 become wider than the example shown in FIG. 22.

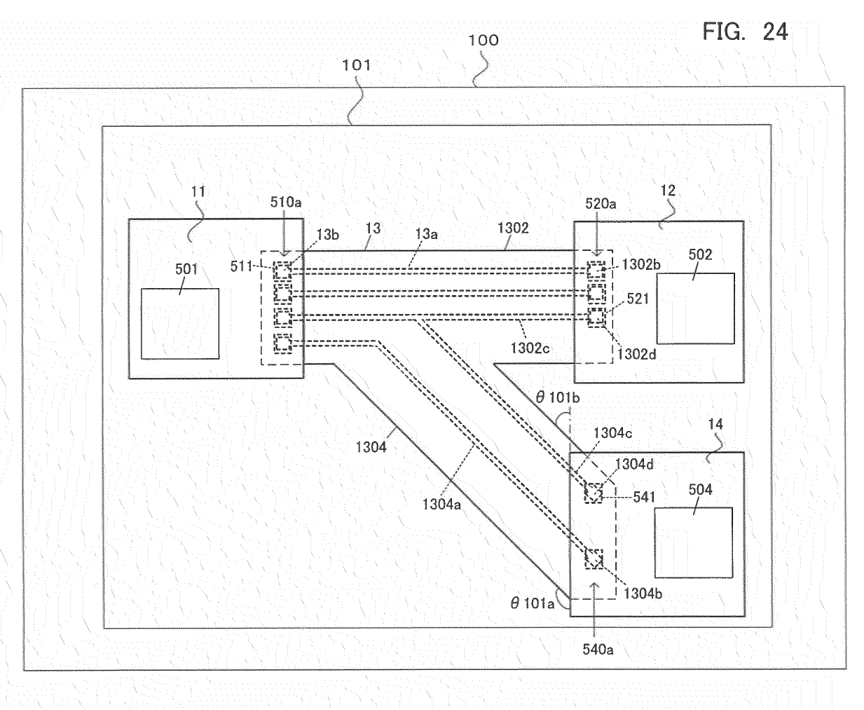

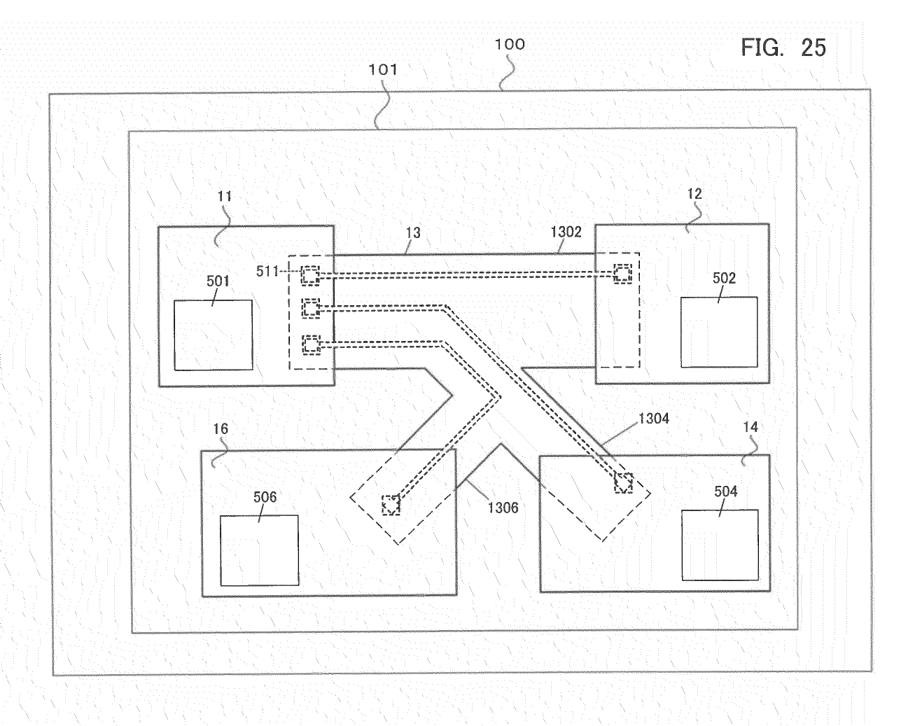

Also, the structure may be made in such a way that a flexible printed wiring board has at least one fork. For example, as shown in FIG. 24, flexible substrate 13 may be forked to have two bifurcated routes 1302, 1304 and at each tip of the bifurcated routes, rigid substrates 12, 14 may be connected. In the example shown in FIG. 24, at the connection section of rigid substrate 14, angle (θ101a) is set at 135 degrees, and angle (θ10b) is set at 45 degrees.

Also, as shown in FIG. 25, for example, the flexible substrate is branched off to have three bifurcated routes 1302, 1304, 1306. At each tip of the bifurcated routes, rigid substrates 12, 14, 16 (each with a mounted electronic component 502, 504 or 506) may be connected respectively. The number of branches is not limited to any specific number.

The connection angle or forked angle is not limited to any degree, as long as it is acute or obtuse. Therefore, such an angle may be set at 60° or 120° in addition to the above mentioned angles of 30°, 45°, 135° and 150°.

The structure may also be made in such a way that each multiple flexible printed wiring board connects a single rigid printed wiring board by being shifted in the direction toward the thickness (vertically) of the rigid printed wiring boards.

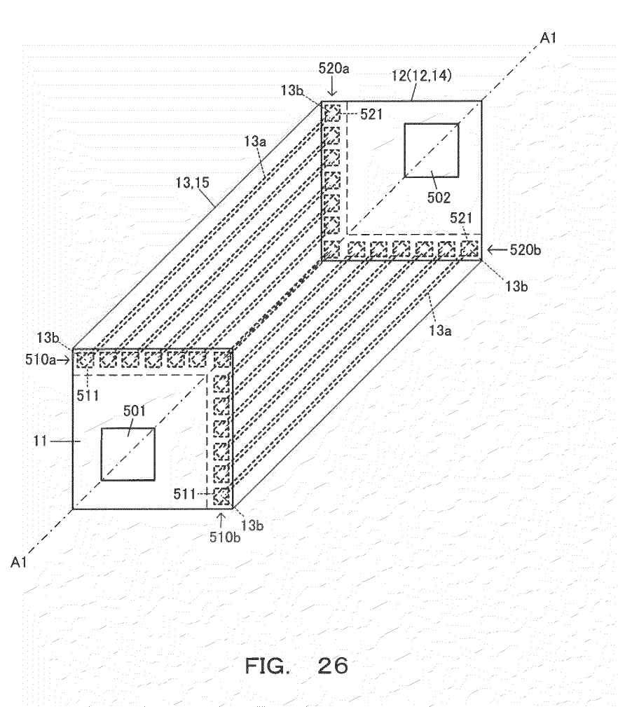

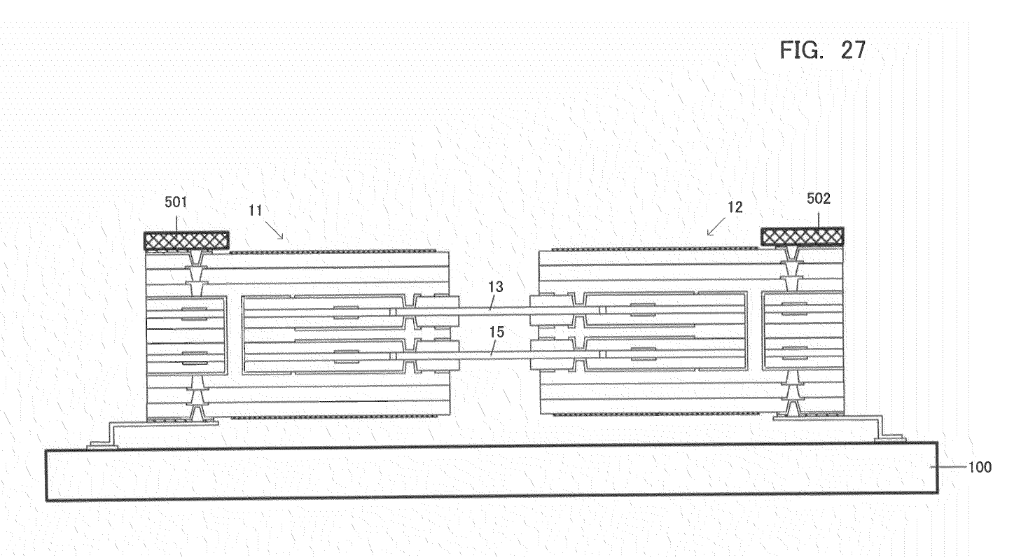

For example, as shown in FIG. 26 (plan view) and FIG. 27 (a cross-sectional view seen from the A1-A1 line of FIG. 26), the structure may be made in such a way that flexible substrates 13, 15 are arranged vertically with a predetermined space in between and one tip is connected to rigid substrate 11 and the other tip to rigid substrate 12.

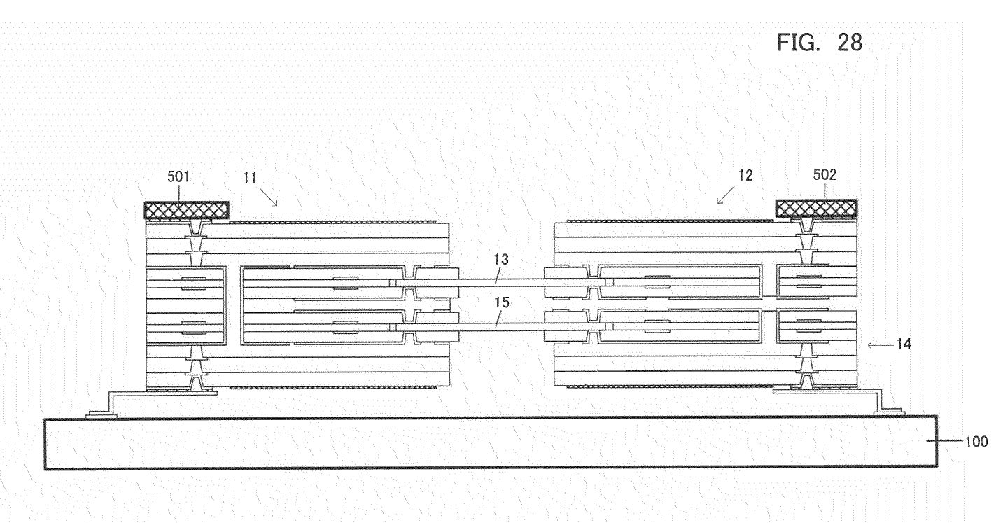

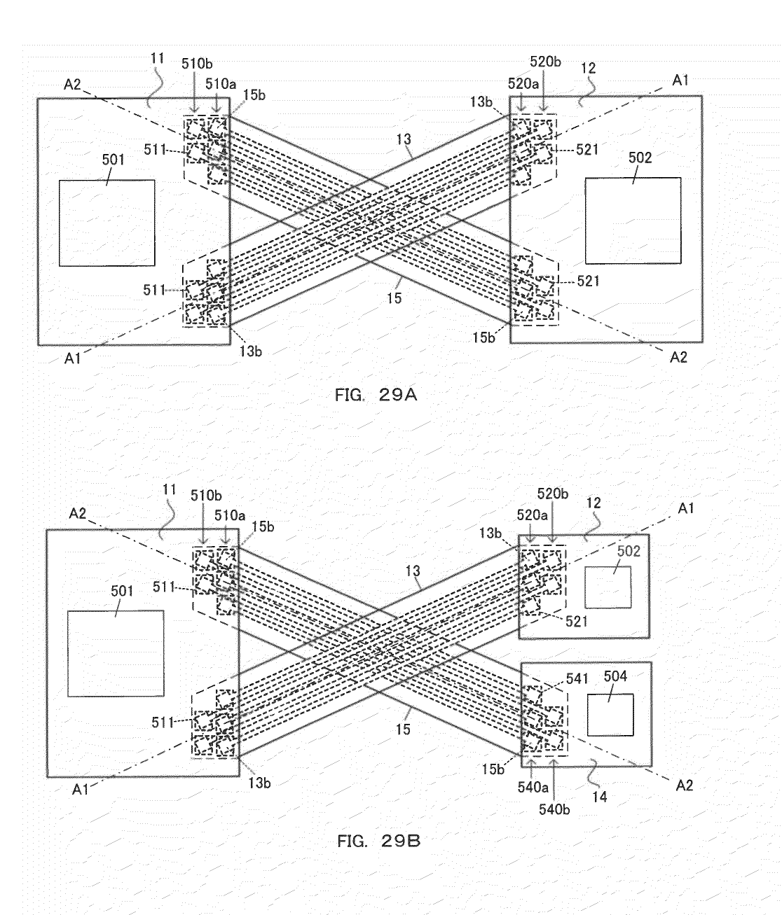

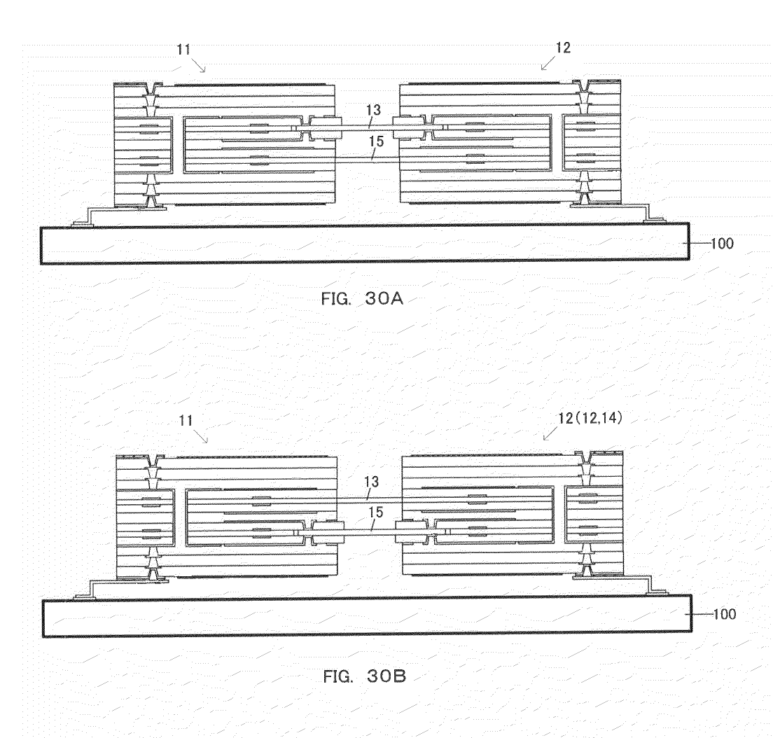

Alternatively, for example, as shown in FIG. 26 (a plan view) and FIG. 28 (a cross-sectional view seen from the A1-A1 line of FIG. 26), the structure may be made in such a way that one tip each of flexible substrates 13, 15 is connected to common rigid substrate 11, and the other tip of flexible substrate 13 is connected to rigid substrate 12 and the other tip of flexible substrate 15 to rigid substrate 14. In such an example, rigid substrates 12, 14 are arranged vertically with a predetermined space in between.

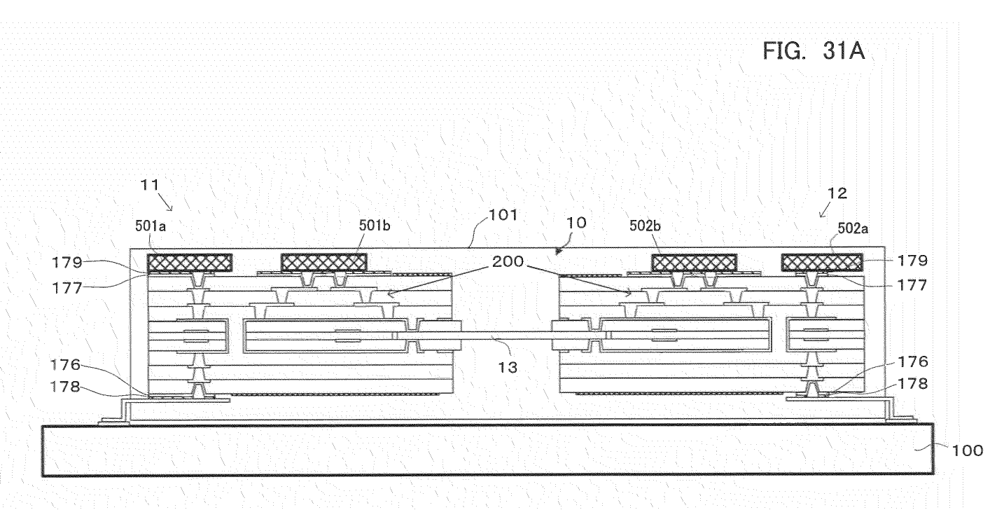

Also, for example, as shown in FIG. 29A or FIG. 29B, flexible substrates 13, 15, which are shifted from each other in the direction toward the thickness (vertically) of rigid substrates 11, 12 (or rigid substrates 11, 12, 14), may be arranged to cross each other. FIGS. 30A and 30B are cross-sectional views common to FIGS. 29A and 29B. FIG. 30A is a cross-sectional view seen from the A1-A1 line, and FIG. 30B is a cross-sectional view seen from the A2-A2 line.

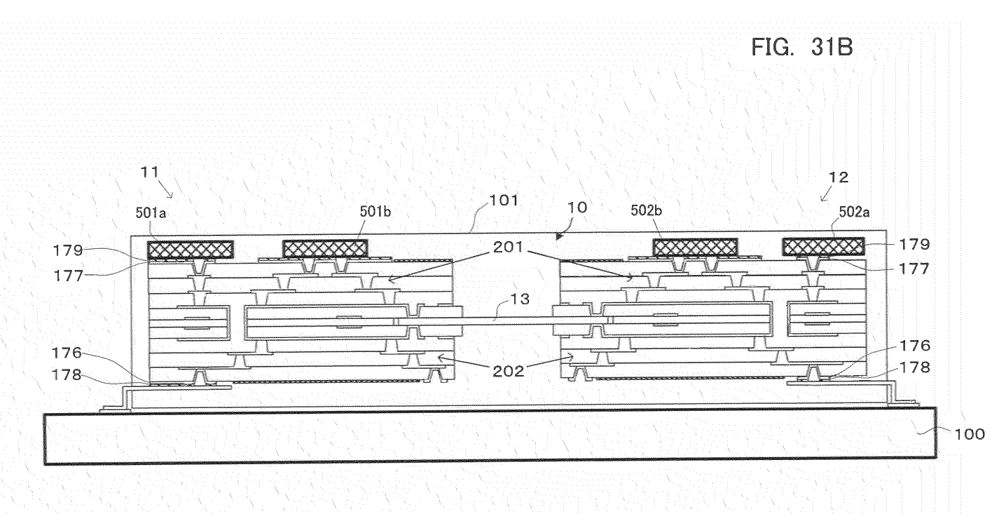

The structure may be made in such a way that, as shown in FIG. 31A, conductive patterns in rigid substrates 11, 12 have configurations (fanned-out conductive patterns 200) which fan out from component connection terminals (electrodes 179) to board connection terminals (electrodes 178). Specifically, in flex-rigid wiring board 10 shown in FIG. 31A, the average distance between component connection terminals is made smaller than the average distance between board connection terminals. Here, the average distance between component connection terminals indicates an average value between component connection terminals (electrodes 179) to which electronic component 501 is connected; and the average distance between board connection terminals indicates an average value between board connection terminals (electrodes 178) which are connected to motherboard 100.

Also, as shown in FIG. 31B, the structure may be configured in such a way (via patterns 201, 202) that multiple vias are formed in each layer of rigid substrates 11, 12, and the spaces between such multiple vias (for example, an average distance) widen from one main surface where component connection terminals (electrodes 179) are formed toward the other main surface where board connection terminals (electrodes 178) are formed.

By employing such structures, electronic components (501a, 501b, 502a, 502b) having high-density wiring with narrower pitches than in motherboard 100 may be mounted on motherboard 100 through rigid substrates 11, 12.

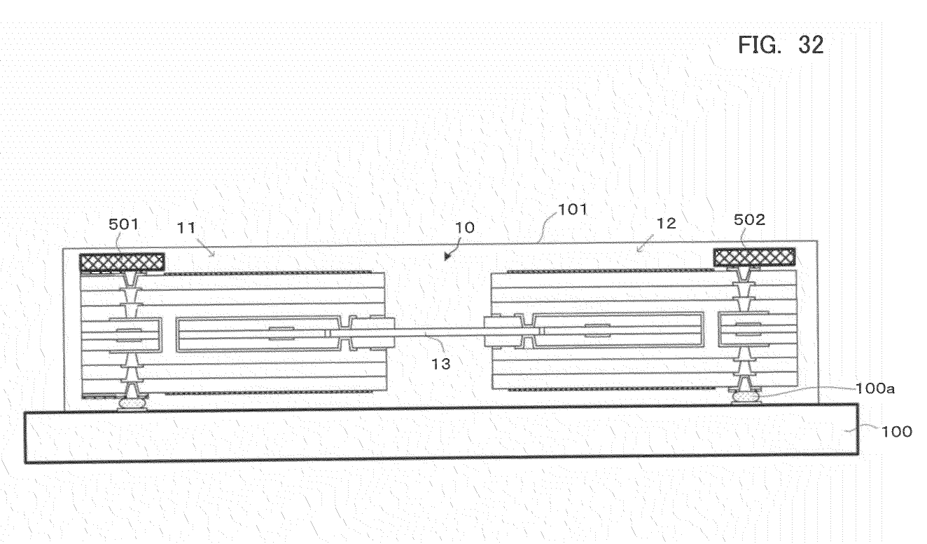

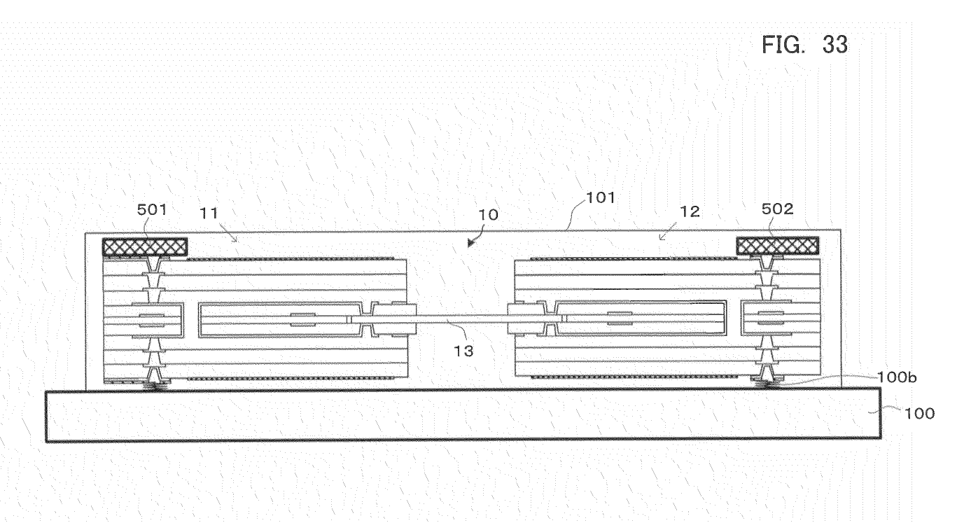

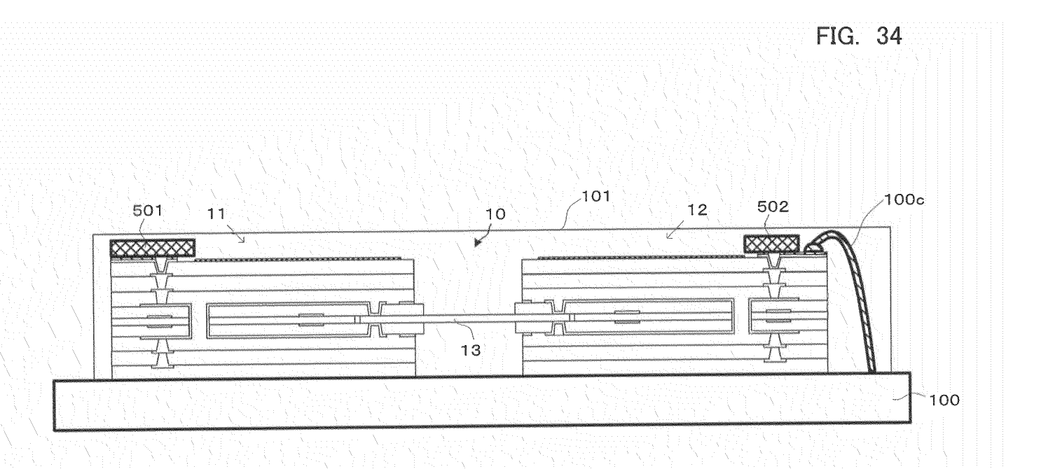

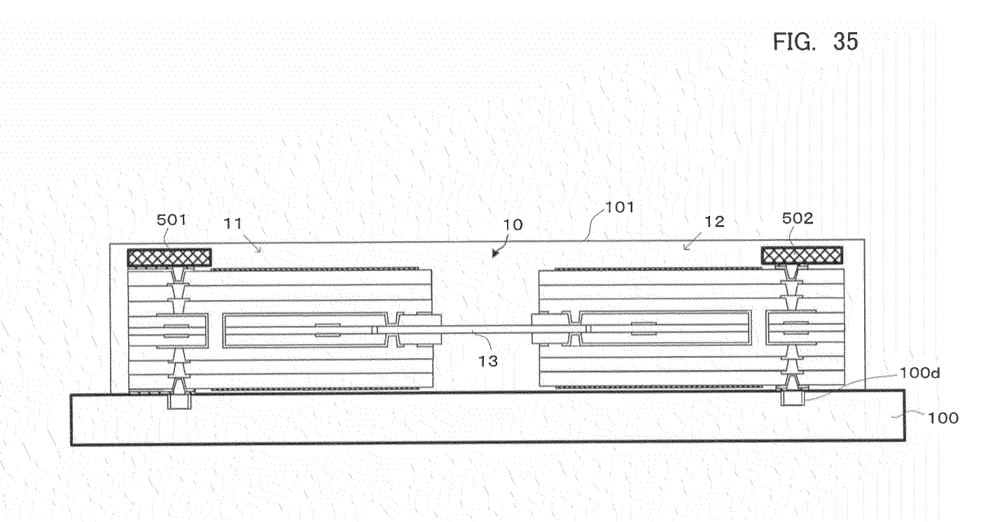

When mounting flex-rigid wiring board 10 on motherboard 100, a bare chip may be mounted directly, not by means of packaging 101. For example, as shown in FIG. 32, a bare chip may be mounted on motherboard 100 by a flip-chip connection using, for example, conductive adhesive agent (100a). Alternatively, for example, as shown in FIG. 33, a bare chip may be mounted on motherboard 100 by means of spring (100b). Also alternatively, for example, as shown in FIG. 34, a bare chip may be mounted on motherboard 100 by wire bonding through wiring (100c). Also alternatively, for example, as shown in FIG. 35, build-up vias are formed all the way to the upper layer of motherboard 100, and both substrates may be electrically connected by means of section through-holes (plated through-holes) (100d). Also, both substrates may be electrically connected through connectors. Any method may be employed for mounting both substrates.

Furthermore, the material for the electrodes and wiring to electrically connect both substrates is not limited to a specific type. For example, both substrates may be electrically connected by ACF (Anisotropic Conductive Film) connection or Au—Au connection. It may be easier to use ACF connection to align flex-rigid wiring board 10 and motherboard 100. Also, using an Au—Au connection, connected sections may be formed to be corrosion-resistant.

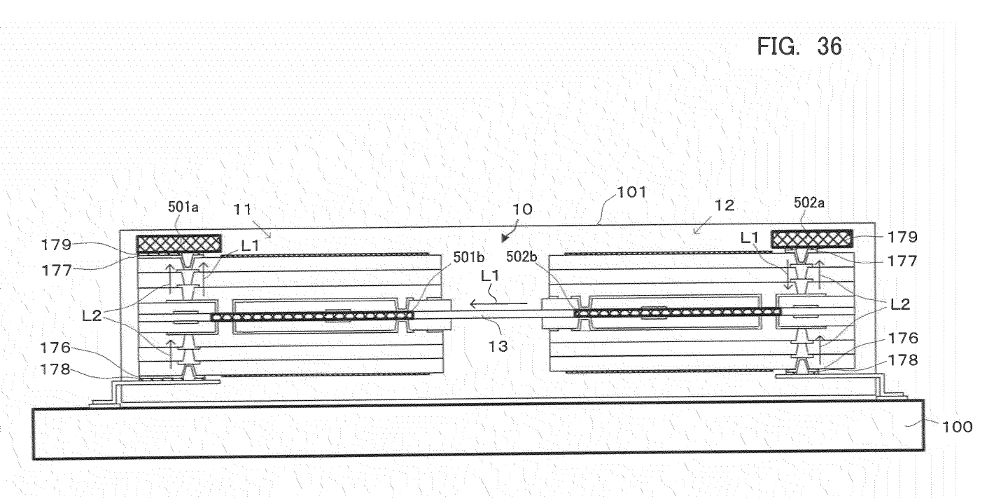

In addition to electronic components (501a, 502a) mounted on a surface of flex-rigid wiring board 10, electronic components (501b, 502b) may be built into flex-rigid wiring board 10 as shown in FIG. 36. By using flex-rigid wiring board 10 with built-in electronic components, electronic devices may be made highly functional. Here, electronic components (501b, 502b) may be, for example, active components such as an IC circuit or the like, or passive components such as a resistor, condenser (capacitor) or coil.

In the above embodiment, the option exists to modify the material and size of each layer and the number of layers. For example, instead of a prepreg, an RCF (Resin Coated Copper Foil) may be used.

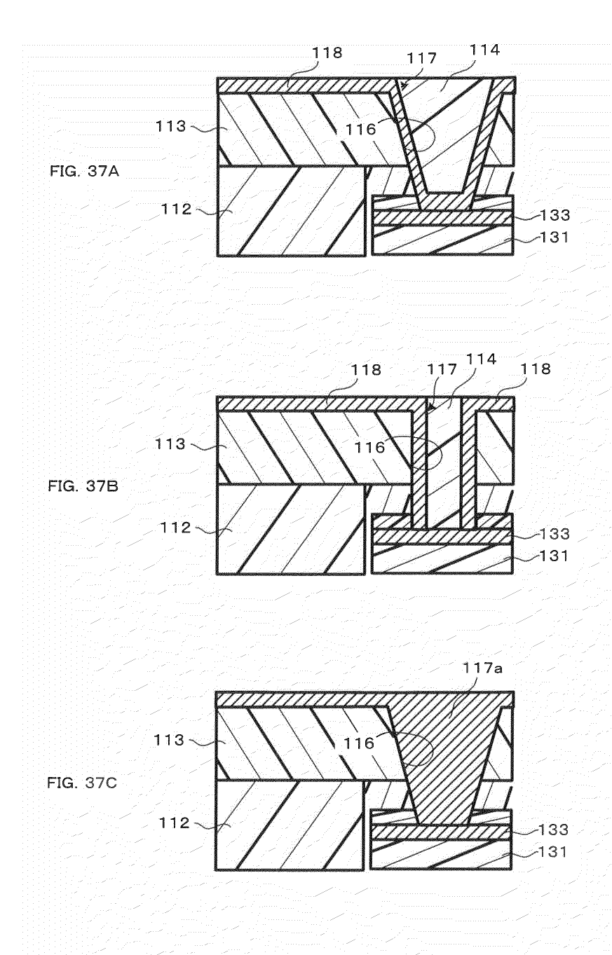

Also, in the above embodiment, as shown in FIG. 37A, rigid substrates 11, 12 and flexible substrate 13 were electrically connected respectively through filled conformal vias in second upper-layer insulation layer 114 (insulation resin) (see FIG. 6 for detail). However, the present invention is not limited to such. For example, as shown in FIG. 37B, both substrates may be connected by through-holes. However, in such a structure, the impact of being dropped or the like may concentrate in the inner-wall portions of the through-holes, and thus cracks may more easily occur at the shoulder sections of through-holes, compared with conformal vias. Other than such, for example, as shown in FIG. 37C, both substrates may be connected with filled vias by filling conductors (117a) in vias 116. In such a structure, the impact of being dropped or the like may be exerted on the entire vias, thus cracks occur less frequently than in conformal vias. The interiors of such conformal vias and through-holes may be filled with conductive resin.

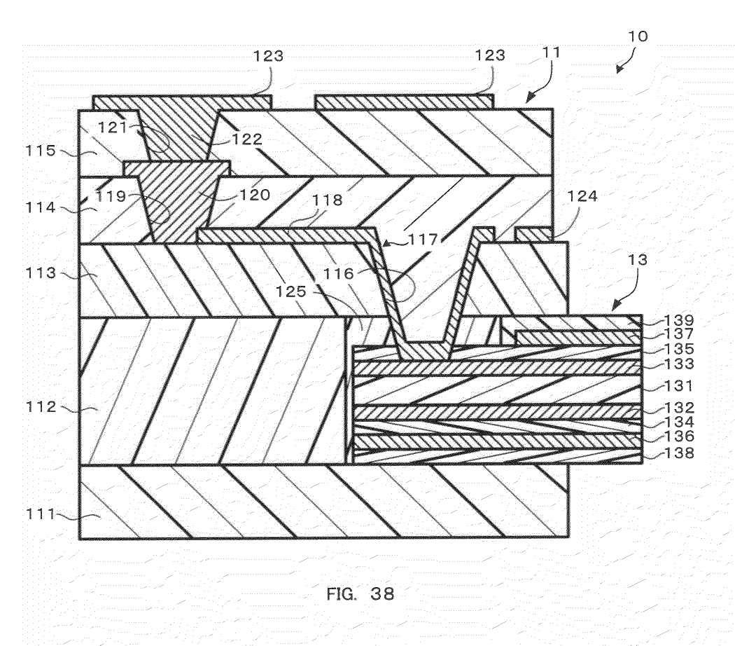

Also, as shown in FIG. 38, rigid substrate 11 may have conductors (wiring layers) only on either the front or the back of the core (the same as in other rigid substrates).

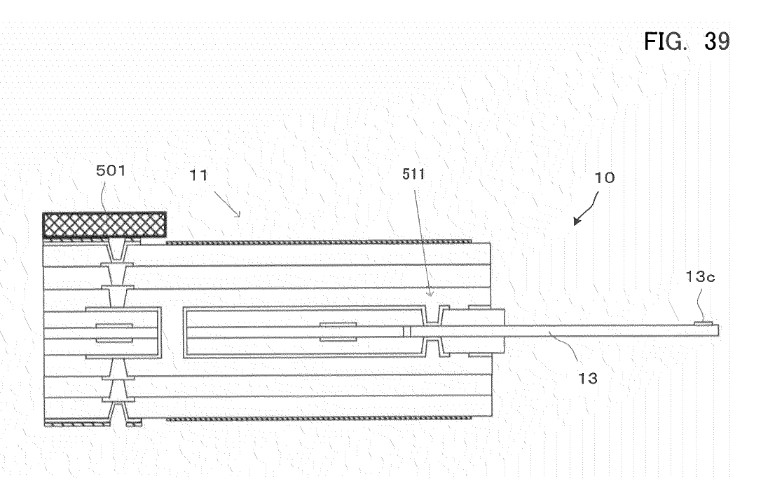

Also, as shown in FIG. 39, without connecting first rigid substrate 11 and second rigid substrate 12, a structure, for example, in which flexible substrate 13 protrudes from rigid substrate 11 in the shape of a tail, a so-called flying-tail structure, may be employed. In the example shown in FIG. 39, part of the inner-layer pattern is extended from rigid substrate 11 to be electrically connected to another substrate or electronic device through terminals (13c) formed at a tip of flexible substrate 13.

A flex-rigid wiring board according to the first aspect of the present invention is formed with a rigid printed wiring board and a flexible printed wiring board having a flexible base material. The flex-rigid wiring board has the following: the flexible printed wiring board has a first conductor on the flexible base material; the rigid printed wiring board has a second conductor; the first conductor and the second conductor are electrically connected; and the flexible printed wiring board connects to the rigid printed wiring board and extends from the connected section in a direction that makes either an acute angle or an obtuse angle with an exterior side of the rigid printed wiring board.

A flex-rigid wiring board according to the second aspect of the present invention is formed with a rigid printed wiring board and a flexible printed wiring board having a flexible base material. The flex-rigid wiring board has the following: the flexible printed wiring board has a first conductor on the flexible base material; the rigid printed wiring board has a second conductor; the rigid printed wiring board has a terminal formed from the second conductor; the flexible printed wiring board, in which the first conductor is formed, is connected to at least two adjacent sides of the rigid printed wiring board; and the first conductor and the terminal are electrically connected.

An electronic device according to the third aspect of the present invention has the flex-rigid wiring board being mounted on a motherboard by means of board connection terminals.

Obviously, numerous modifications and variations of the present invention are possible in light of the above teachings. It is therefore to be understood that within the scope of the appended claims, the invention may be practiced otherwise than as specifically described herein.

What is claimed is:

1. A flex-rigid wiring board comprising:
a rigid printed wiring board having a rectangular shape and comprising a rigid base material and a conductor; and
a flexible printed wiring board comprising a flexible base material and a conductor formed over the flexible base material, the conductor of the flexible printed wiring board being electrically connected to the conductor of the rigid printed wiring board,
wherein the flexible printed wiring board is connected to the rigid printed wiring board and extends from at least one side of the rectangular shape of the rigid printed wiring board such that the flexible printed wiring board extends in a direction which makes an acute angle with respect to the one side of the rectangular shape of the rigid printed wiring board.

2. The flex-rigid wiring board according to claim 1, wherein the rectangular shape of the rigid printed wiring board is a square shape.

3. The flex-rigid wiring board according to claim 1, wherein the acute angle is set at 45 degrees.

4. The flex-rigid wiring board according to claim 1, wherein the flexible printed wiring board has at least one bifurcated section.

5. The flex-rigid wiring board according to claim 1, further comprising a plurality of rigid printed wiring boards connected to other ends of the flexible printed wiring board.

6. The flex-rigid wiring board according to claim 1, further comprising a second flexible printed wiring board, wherein the flexible printed wiring board and the second flexible printed wiring board are connected to the rigid printed wiring board such that the flexible printed wiring board and the second flexible printed wiring board are shifted in a thickness direction of the rigid printed wiring board.

7. The flex-rigid wiring board according to claim 1, wherein the flexible printed wiring board has an embedded portion embedded in the rigid printed wiring board, and the conductor of the flexible printed wiring board is electrically connected to the conductor of the rigid printed wiring board at the embedded portion.

8. The flex-rigid wiring board according to claim 1, wherein the rigid printed wiring board further comprises an insulation layer covering the flexible printed wiring board while exposing at least a portion of the flexible printed wiring board, the conductor of the rigid printed wiring board is formed on the insulation layer, and the conductor of the flexible printed wiring board is connected to the conductor on the insulation layer via a plated film penetrating through the insulation layer.

9. The flex-rigid wiring board according to claim 1, wherein the rigid printed wiring board has a plurality of component connection terminals positioned to mount an electronic component on a first surface of the rigid printed wiring board, the rigid printed wiring board has a plurality of board connection terminals positioned to be mounted to a mother board on a second surface of the rigid printed wiring board, and the component connection terminals are provided at an average distance which is made smaller than an average distance between the board connection terminals.

10. The flex-rigid wiring board according to claim 9, wherein the rigid printed wiring board includes a plurality of vias, and the vias are provided with spaces which widen from the first surface toward the second main surface.

11. The flex-rigid wiring board according to claim 1, wherein the rigid printed wiring board has a plurality of board connection terminals positioned to be mounted to a motherboard.

12. The flex-rigid wiring board according to claim 11, wherein the rigid printed wiring board has a plurality of component connection terminals positioned to mount an electronic component on a surface of the rigid printed wiring board, and the conductor of the rigid printed wiring board is fanning out from the component connection terminals to the board connection terminals.

13. The flex-rigid wiring board according to claim 1, wherein the conductor of the rigid printed wiring board has a terminal electrically connected to the conductor of the flexible printed wiring board, and the flexible printed wiring board is connected to at least two adjacent sides of the rectangular shape of the rigid printed wiring board.

14. The flex-rigid wiring board according to claim 13, wherein the conductor of the rigid printed wiring board is formed in a plurality, the plurality of conductors of the rigid printed wiring board has a plurality of terminals, respectively, and the plurality of terminals is positioned in a row.

15. An electronic device comprising:
a motherboard; and
a flex-rigid wiring board mounted on the motherboard and comprising a rigid printed wiring board and a flexible printed wiring board,
wherein the rigid printed wiring board has a rectangular shape and includes a rigid base material and a conductor, the flexible printed wiring board includes a flexible base material and a conductor formed over the flexible base material, the conductor of the flexible printed wiring board is electrically connected to the conductor of the rigid printed wiring board, the flexible printed wiring board is connected to the rigid printed wiring board and extends from at least one side of the rectangular shape of the rigid printed wiring board such that the flexible printed wiring board extends in a direction which makes an acute angle with respect to the one side of the rectangular shape of the rigid printed wiring board, and the rigid printed wiring board has a plurality of board connection terminals mounted to the motherboard.

16. The electronic device according to claim 15, further comprising an electronic component mounted on a surface of the rigid printed wiring board.

17. The electronic device according to claim 16, wherein the electronic component has a logic operation function.

18. The flex-rigid wiring board according to claim 15, wherein the rectangular shape of the rigid printed wiring board is a square shape.

19. The flex-rigid wiring board according to claim 15, wherein the acute angle is set at 45 degrees.

20. The flex-rigid wiring board according to claim 15, wherein the rigid printed wiring board has a plurality of component connection terminals positioned to mount an electronic component on a surface of the rigid printed wiring board, and the conductor of the rigid printed wiring board is fanning out from the component connection terminals to the board connection terminals.
